(19) United States
(12) Patent Application Publication
(10) Pub. No.: US 2022/0068610 A1
(43) Pub. Date: Mar. 3, 2022

(54) VACUUM TREATMENT APPARATUS AND METHOD FOR VACUUM PLASMA TREATING AT LEAST ONE SUBSTRATE OR FOR MANUFACTURING A SUBSTRATE

(71) Applicant: EVATEC AG, Trrübbach (CH)

(72) Inventors: Edmund Schüngel, Buchs (CH); Silvio Gees, Bad Ragaz (CH); Adrian Herde, Hombrechtikon (CH)

(21) Appl. No.: 17/415,912

(22) PCT Filed: Dec. 13, 2019
(86) PCT No.: PCT/EP2019/085097

§ 371 Date: Jun. 18, 2021

(30) Foreign Application Priority Data
Dec. 21, 2018 (CH) 01586/18

(51) Int. Cl. H01J 37/32; H01J 37/34; C23C 14/54; C23C 14/35; C23C 14/00; C23C 14/50

(52) U.S. Cl. CPC H01J 37/32541; H01J 37/32577; H01J 37/3255; H01J 37/3299; H01J 37/3405; H01J 2237/332; C23C 14/54; C23C 14/35; C23C 14/0036; C23C 14/505; H01J 2237/002; H01J 37/3426

(57) ABSTRACT

In a vacuum treatment recipient, a plasma is generated between a first plasma electrode and a second plasma electrode so as to perform a vacuum plasma treatment of a substrate. To minimize at least one of the two plasma electrodes to be buried by a deposition of material resulting from the treatment process, that electrode is provided with a surface pattern of areas which do not contribute to the plasma electrode effect and of areas which are plasma electrode effective. The current path between the two electrodes is concentrated on the distinct areas which are plasma electrode effective, leading to an ongoing sputter- cleaning of these areas.

The present invention resides in the technical field of treating substrates in vacuum with the help of a plasma established between two plasma electrodes, by which treatment there is generated, in a reaction space to which the plasma electrodes are exposed, a material which deposits on at least one of the plasma electrodes and which may lead to process instabilities.

It is an object of the invention to at last reduce drifting of such a substrate treatment process over time, including long-time drifting i.e. drifting between maintenance intervals of the treatment apparatus.

This is achieved by a vacuum plasma treatment apparatus which comprises, within a vacuum recipient, at least one first and at least one second plasma electrode for generating a plasma therebetween.

The first and the second plasma electrodes are connectable to an electric plasma supply source arrangement which establishes a first electric potential to the first plasma electrode and a second electric potential to the second plasma electrode, whereby the first and the second electric potentials are both independently variable with respect to a system ground potential, as e.g. applied to the wall of the vacuum recipient.

At least the first plasma electrode comprises an electrode body with an outer, patterned surface comprising first surface areas noncontributing to the plasma electrode effect and being of a metallic material or of a dielectric material and second surface areas being plasma electrode effective and being of a metallic material or being the surface of a dielectric material layer deposited on metallic material, the metallic material being operated on the first electric potential.

### Definitions

we understand throughout the present description and claims under a “substrate” a single workpiece or a batch of workpieces commonly treated in the reaction space. The workpieces may be of any shape and material, are nevertheless especially plate shaped, flat or curved.
whenever the plasma supply source arrangement—which may comprise one or more than one power generators—generates a difference of electric potentials between the first and the second plasma electrodes, a plasma discharge voltage, the frequency spectrum thereof comprising a DC component, then and dependent on the polarity of the DC component, one electrode is an anode, the other is a cathode. In this case the “first plasma electrode”, as addressed throughout the present description and claims, is an anode.
whenever the addressed spectrum has no DC component, one may not identify the plasma electrodes as anode or as cathode. In these cases, the first plasma electrode addresses that plasma electrode which is not to be consumed for the substrate treatment. Thus e.g. for sputter-deposition of layers on substrates or for etching substrates, the target electrode or the substrate on a substrate carrier, as a plasma electrode, is to be consumed and the “first plasma electrode” addresses that electrode which is not target electrode or that electrode, on which the substrate to be etched does not reside.
whenever the addressed spectrum has no DC component, and none of the plasma electrodes is to be consumed for the substrate treatment as e.g. in plasma enhanced CVD, then the first plasma electrode addresses either one of the plasma electrodes and even the second plasma electrode may be constructed according to the features described and claimed for the first plasma electrode.
Under the term “metallic material” we understand any material including metals with an electrical conductivity equal or similar to that of metal material, but also e.g. graphite, conductive polymers, semiconductor materials or respectively doped materials.
We understand under “ surface areas noncontributing to the plasma electrode effect” of a plasma electrode surface area, which are explicitly provided for the purpose of noncontributing to the electrode effect. Thus, and as an example, openings in the surface of the electrode body for feeding a gas into the vacuum recipient have explicitly the purpose of gas feeding and are not to be considered as “surface areas noncontributing to the plasma electrode effect” even if the surface areas of such openings do not contribute to the plasma electrode effect. The “surface areas noncontributing to the plasma electrode effect” are loaded with a much smaller practically neglectable current fraction from the current passing between the two plasma electrodes and along the plasma than “surface areas being plasma electrode effective” and as defined bellow, on which the addressed current is concentrated.
We understand under “surface areas being plasma electrode effective” surface areas which, appropriately electrically supplied, lead to a plasma burning between the second electrode and such surface areas. It is on these distinct “surface areas being plasma electrode effective” that the current passing between the two plasma electrodes and along the plasma concentrates.
We understand under “new state” of an electrode, an electrode which has yet not been affected by a plasma treatment process.

It is known that both plasma electrodes are subjected to sputtering as well as to material deposition. Which of the two processes is the predominant one at one of the plasma electrodes considered, depends on the purpose of that electrode within the plasma treatment process. If one of these processes is predominant there results net sputtering or net deposition.

E.g. for sputter-deposition, the purpose of a target plasma electrode is to be predominantly sputtered. Nevertheless, some material deposition occurs also on the target, known in context with target-poisoning. The counter plasma electrode to the target electrode is predominantly subjected to material deposition which leads to so called “buried” electrode or “vanishing” electrode or “disappearing” electrode or -anode.

If such counter plasma electrode has a metallic material surface any growing deposition of material thereon with a lower electroconductivity than that of the metallic material of the surface in new state, will destabilize the process.

If the plasma is supplied by Rf, the surface of one or even of both plasma electrodes may be of a dielectric material, capacitively coupling the Rf supply signal to the plasma. In these cases a growing deposit of a dielectric material on a new state dielectric surface plasma electrode will as well lead to destabilization of the process.

It has been recognized by the inventors, that as the addressed body of the first plasma electrode has a surface which is patterned in first surface areas -NPL- noncontributing to the plasma electrode effect and in surface areas -PL-, which are plasma electrode effective, the plasma supplying electric field and thus the current path between the first and the second plasma electrodes, may be said to be focused or concentrated on the PL surface areas which leads to the fact, that only the NPL's are, predominantly or even exclusively, subjected to deposition of material, whereas, at the PL surface areas, the surface material exposed to the plasma remains substantially unaffected, i.e. clean from material deposits.

Details about the processes along the surface of the electrode body according to the invention will also become apparent to the skilled artisan in context with different embodiments of that body as addressed below.

In one embodiment of the vacuum plasma treatment apparatus according to the invention, in a new state of at least the first plasma electrode , and in a projection of the pattern on an envelope locus of the body, the ratio Q of the sum of projection areas of the second surface areas -PL- to the sum of projection areas of the first surface -NPL- areas of the pattern is
0.1≤Q≤9.

This accords to a range of ratio of projected surface areas PL to (PL+NPL) of about 10% to about 90%.

In one, today successfully practiced embodiment of the vacuum plasma treatment apparatus according to the invention, in a new state of at least the first plasma electrode , and in a projection of the pattern on an envelope locus of the body, the ratio Q of the sum of projection areas of the second surface areas -PL- to the sum of projection areas of the first surface areas -NPL- of the pattern is
0.4≤Q≤1.

This accords to a range of ratio of projected surface areas PL to (PL+NPL) of about 30% to about 50%.

In one embodiment of the vacuum plasma treatment apparatus at least some of the second surface areas-PL- and at least some of the first surface areas -NPL- are metallic material surface areas, in a new state of at least the first plasma electrode.

In this embodiment the addressed first -NPL- surface areas confine spaces wherein, due to geometric dimensioning, plasma may not burn.

In one embodiment of the vacuum plasma treatment apparatus at least some of the first surfaces areas -NPL- are dielectric material surface areas and at least some of the second surface areas -PL- are metallic material surface areas, in a new state of at least the first plasma electrode.

In this embodiment too, the dielectric material of the first surface areas -NPL- leads to concentrating the electric field and the current path on the second -PL- surface areas.

In one embodiment of the vacuum plasma treatment apparatus according to the invention at least some of the first surface areas -NPL-and at least some of the second surface areas -PL- are dielectric material surface areas, in a new state of at least the first plasma electrode.

This embodiment is suited for Rf plasma supply whereat dielectric constants and thickness of the respective dielectric materials govern the resulting impedances.

In one embodiment of the vacuum plasma treatment apparatus according to the invention the body comprises a core and an envelope and the pattern of the patterned surface is defined by the envelope.

The envelope may thereby carry the pattern of first surface areas -NPL- and of the second surface areas -PL- or may, practically as a grid, form the first or second surface areas, leaving, respectively, the second or first surface areas freely accessible on the surface of the core.

Such envelope may be a maintenance replacement part.

In one embodiment of the vacuum plasma treatment apparatus according to the invention, the second surface areas -PL- are of a metallic material in a new state of at least the first plasma electrode , and the vacuum plasma apparatus is constructed to generate, in operation, material in a space in the vacuum recipient exposed to at least the first plasma electrode, which material is electrically less conductive than the metallic material of the second surface areas -PL-.

Although the electrode body may in fact be of any suited shape, in one embodiment of the apparatus according to the invention, the electrode body extends along a straight axis, which facilitates integration in the overall apparatus. Moreover, the fact, that the first electrode according to the invention is highly localized in the vacuum recipient, is strengthened by realizing the electrode body along the straight axis. Please note that common prior art realizations of the first electrode are rather undefined with respect to localization in the vacuum recipient, due to the fact, that often the wall of the vacuum recipient is used as first electrode operated on system ground potential.

In one embodiment of the vacuum plasma treatment apparatus according to the invention the electrode body is surrounded by a geometric locus-body which has an elliptical or a circular or a polygonal cross section.

In one embodiment of the vacuum plasma treatment apparatus according to the invention the electrode body is surrounded by a geometric locus-body having, considered in one direction, a tapering cross-section contour.

Thereby the distribution of the material-deposition effect and of the material-sputtering effect along the body of the first plasma electrode may be tuned, especially accurately homogenized.

In one embodiment of the vacuum plasma treatment apparatus according to the invention, the first surface areas -NPL- of the patterned surface comprise at least one of
a void recess having a metallic material surface;
a void recess having a metallic material surface covered by a layer of a dielectric material;
a recess having a metallic material surface and filled with dielectric material.

It is perfectly known to the artisan skilled in the art or field as addressed above, that recesses in a metallic material surface exposed to a plasma may be filled with the plasma or may be void of the plasma, dependent on the dimensioning of such recesses. Thus, one embodiment of realizing the electrode body is to provide recesses in the metallic material surface tailored to prevent plasma occurring therein. This is accomplished by considering, as known in the art, the prevailing darkspace-distance, also called “plasma sheath” distance, in the process for which the respective apparatus is tailored. Void of plasma, the electric conductance in the recesses is relatively small and there is only a weak ion-accelerating electric potential gradient in the recesses which does not suffice to predominantly sputter the surface in the recesses: The material out of the reaction space just deposits in the recesses, leading to a growing layer in the recesses of a material which is possibly electrically less conductive than the metallic material whereon such layer is deposited.

In other words, in the case that the material generated by the respective process, e.g. by reactive magnetron sputtering or by etching, is electrically less conductive than the metallic material, the overall metallic material surface of the body of the first electrode is reduced and the electric field is focused on the remaining metallic material surfaces aside the recesses and exposed to the plasma i.e. on the second surface areas -PL- of the addressed pattern. The result is an increased electric potential gradient across the plasma sheath, increase of ion acceleration towards the metallic material surface of the second surface areas -PL- and thus increased cleaning-sputtering or etching of these metallic material surfaces aside the recesses. The remaining metallic material areas and thus the second surface areas -PL- along the electrode body stay clean from deposits which leads to a stable electrode effect of the electrode body and thus of the process.

The mere growing of a material layer with a relatively low electrical conductivity in the recesses as addressed above may still lead to a process drift. Therefore, and in one embodiment, instead or additionally to providing void recesses as the first surface areas -NPL-, at least some first surface areas -NPL-are realized by a void in the metallic material, covered by a layer of a dielectric material, e.g. a ceramic material. Thereby, the electrode effect of the body becomes stable just from the beginning of the plasma process, the metallic material second surface areas -PL- stay clean just from the start of the plasma treatment.

Instead or additionally to providing void recesses in the metallic material and/or of providing void recesses in the metallic material covered by a layer of dielectric material, a further embodiment provides recesses as well in the metallic material, but filled with dielectric material, as with ceramic material

Instead of providing voids in the metallic material surface of the body—or of its envelope—and then to fill or coat such recesses with a dielectric material, the metallic material surface may be provided with a surface pattern of dielectric material areas on metallic material which provides for the first surface areas -NPL-.

If the first electrode is a plasma electrode for a Rf plasma, then also the second surface areas -PL- of the pattern may be made of dielectric material. In this case the dielectric material pattern of the second surface areas -PL- on metallic material are made thinner than the dielectric material pattern of the first surface areas -NPL- on that metallic material and thus presents a higher capacitive coupling to the plasma than the first surface areas -NPL- and/or the dielectric constant of the dielectric material of the second surface areas is larger than the dielectric constant of the dielectric material of the first surface areas.

As perfectly apparent to the artisan skilled in the addressed art, there exists a huge number of possibilities to realize the electrode body according to the invention.

In one embodiment of the vacuum plasma treatment apparatus according to the invention the electrode body extends along an axis, and the first surface areas -NPL- comprise at least one groove around the axis.

Thereby and in one embodiment of the vacuum plasma treatment apparatus according to the invention, the addressed at least one groove is a helical groove or a ring groove.

In one embodiment of the vacuum plasma treatment apparatus according to the invention, the second surface areas -PL- comprise at least one helical area around an axis of the body. Such helical area may be metallic material area coated on a dielectric material core or on an envelope of that body.

In one embodiment of the vacuum plasma treatment apparatus according to the invention, as just addressed, the helical area of the second surface area -PL- is a metallic material wire.

In one embodiment of the vacuum plasma treatment apparatus as just addressed, the wire is free-standing with the exception of a rigid electric supply connection thereto.

In one embodiment of the vacuum plasma treatment apparatus according to the invention, the first surface areas -NPL- comprise interspaces between projecting webs.

In one embodiment of the vacuum plasma treatment apparatus according to the invention the first surface areas -NPL- comprise at least one interspace between mutually spaced metallic material plates.

In one embodiment of the vacuum plasma treatment apparatus according to the invention the first surface areas-NPL- comprise at least one dielectric material plate sandwiched between metallic material plates.

There results a multi layered sandwich of metal plates on the first electric potential and of dielectric material interlayer plates.

In one embodiment of the vacuum plasma treatment apparatus according to the invention, the body of the first plasma electrode is cooled.

Thereby and in one embodiment of the plasma treatment apparatus according to the invention, the body comprises a channel arrangement for a cooling medium or is mounted to a heat sink.

One embodiment of plasma treatment apparatus according to the invention comprises an impedance element interconnected between a metallic material part of the body of the first plasma electrode and a metallic material part of the apparatus, operated on an electric reference potential, as on system ground potential.

Such impedance element may be one or more than one discrete and interconnected passive impedance elements and/or one or more than one active impedance elements as e.g. FETs, thereby also controllable so as to adjust the overall prevailing impedance before or during plasma operation. By adjusting the impedance element the self-cleaning effect of the second surface areas -PL- may be tuned.

One embodiment of the plasma treatment apparatus according to the invention comprises a negative feedback control loop for controlling at least one of the first electric potential, of the second electric potential, of the electric potential difference.

One embodiment of plasma treatment apparatus according to the invention comprises a negative feedback control loop wherein a measured prevailing entity consists of the first electric potential to be negative feedback controlled and the apparatus comprises a sensing element for the first electric potential with respect to a reference electric potential.

One embodiment of plasma treatment apparatus according to the invention comprises a negative feedback control loop wherein a measured prevailing entity consists of or comprises the first electric potential with respect to a reference potential and comprises a sensing element for the first electric potential with respect to a reference electric potential, the adjusted entity of the negative feedback control loop consisting of or comprising at least one of a reactive gas flow and of the electric potential difference between the first and the second plasma electrodes and the apparatus comprises at least one of an adjustable flow controller for a reactive gas into the vacuum recipient and of an adjustable plasma power supply arrangement for the electric potential difference.

Please note, that the measured prevailing entity may e.g. be a function of the addressed first electric potential, possibly a more than one variable function, and that the adjusted entity may comprise additional physical entities e.g. the pressure in the vacuum recipient.

Thus, as an example, the prevailing voltage of the first plasma electrode with respect e.g. to system ground potential is measured, and this voltage or a function thereof—possibly a multi-variable function thereof—is compared with a desired, preset value of that voltage or of a desired preset function thereof, and a reactive gas flow into the vacuum recipient and/or the voltage or current between the two plasma electrodes is adjusted so, that the measured, prevailing voltage or the prevailing value of the function thereof assumes a minimum difference to the desired, preset value or time course of the voltage or of the function thereof. Generically the preset value may be a constant value or may vary in time in a preset manner.

Providing a negative feedback control loop as addressed above for at least one of the electric electrode potentials, for the electric potential difference between the two plasma electrodes, is considered possibly as an invention per se.

In one embodiment of the plasma treatment apparatus according to the invention the first plasma electrode is enclosed in a housing in the vacuum recipient, the housing being distant from and electrically isolated from the first plasma electrode and having at least one opening exposed to a reaction space in the vacuum recipient and tailored to allow the plasma to establish between the first and the second plasma electrodes through the addressed opening.

In one embodiment of the plasma treatment apparatus according to the invention the housing is cooled.

In one embodiment of the vacuum plasma treatment apparatus according to the invention the housing comprises a channel arrangement for a cooling medium or is mounted to a heat sink.

In one embodiment of the vacuum plasma treatment apparatus according to the invention, at least a part of the housing is of a metallic material and is electrically operated in a floating manner or is electrically connected to a reference electric potential, as to system ground potential.

In one embodiment of the vacuum plasma treatment apparatus according to the invention at least a part of the housing is of a dielectric material.

In one embodiment of the just addressed embodiment of the vacuum plasma treatment apparatus according to the invention, the opening is in the part of dielectric material.

In one embodiment of the vacuum plasma treatment apparatus according to the invention at least a part of the housing , especially a part with the opening, is a maintenance replace-part or the housing comprises, along at least a predominant part of its inner surface, a shield as a maintenance replacement part.

In one embodiment of the vacuum plasma treatment apparatus according to the invention, the housing comprises, along at least a predominant part of its inner surface, a metallic material shield electrically operated in a floating manner or being connected to an electric reference potential, as on system ground potential.

One embodiment of the vacuum plasma treatment apparatus according to the invention comprises a working gas inlet discharging in the housing which inlet is connectable or connected to a working gas reservoir.

In one embodiment of the vacuum plasma treatment apparatus according to the invention the vacuum recipient comprises a working gas inlet connectable or connected to a working gas reservoir and consisting of a working gas inlet discharging in the housing.

In one embodiment of the vacuum plasma treatment apparatus according to the invention, the body of the first plasma electrode is hidden from the lines of sight from the substrate carrier. Thereby deposition of material sputtered off the first plasma electrode is prevented to deposit on the substrates.

In one embodiment of the vacuum plasma treatment apparatus according to the invention, the body is hidden from the lines of sight from the substrate carrier by means of the housing or by means of a stationary or adjustable shutter across the opening of the housing.

In one embodiment of the vacuum plasma treatment apparatus according to the invention, the shutter is of a metallic material and is electrically operated in an electrically floating manner or on an electric reference potential, as to system ground potential.

In one embodiment of the vacuum plasma treatment apparatus according to the invention, the shutter is of a dielectric material.

It has to be noted, that the position of the first plasma electrode, especially if constructed along a straight axis, within the housing as addressed, may be adjustable especially in direction of that axis and the first plasma electrode may even be removed and reintroduced in the housing so as to optimize plasma ignition or, more generically to tune the current path between the first and second plasma electrodes.

In one embodiment of the vacuum plasma treatment apparatus according to the invention, the second plasma electrode is constructed according to the first plasma electrode. Nevertheless, the first and second plasma electrodes need not be equally constructed. This may be practiced, if none of the first and second plasma electrodes, per their purpose, does materially contribute to the material deposited on a substrate, as e.g. in a PECVD treatments.

In one embodiment of the vacuum plasma treatment apparatus according to the invention, the second plasma electrode is a target or a target holder of a magnetron sputtering source or a substrate holder or a substrate of a plasma etching source having a source anode consisting of the first plasma electrode.

Thus, at such a magnetron sputtering source or etching source, the customarily provided source “anode” is omitted which simplifies the source.

In one embodiment of the vacuum plasma treatment apparatus according to the invention, the second plasma electrode is a target of a magnetron sputtering source, the target being of silicon.

In one embodiment of the vacuum plasma treatment apparatus according to the invention, the vacuum recipient comprises a reactive gas inlet connectable or connected to a reactive gas reservoir. In one embodiment of the vacuum plasma treatment apparatus according to the invention such reactive gas is one of not supplied hydrogen and of oxygen.

In one embodiment of the just addressed embodiment of the vacuum plasma treatment apparatus according to the invention, the second electrode is a magnetron sputter target of silicon.

In one embodiment of the vacuum plasma treatment apparatus reactive gas is not fed to a housing wherein the first electrode resides.

One embodiment of the vacuum plasma treatment apparatus according to the invention comprises a first number of the second plasma electrodes and a second number of the first plasma electrodes whereby the second number is smaller than the first number.

In one embodiment of the vacuum plasma treatment apparatus according to the invention, the first number is at least two and the second number is one. Thus e.g. one single first plasma electrode may be provided serving more than one plasma of at least two plasma treatment stations operating in a common vacuum recipient. Thereby at least two of the at least two plasma may be operated subsequently or simultaneously.

One embodiment of the vacuum plasma treatment apparatus according to the invention comprises:
Within the vacuum recipient, a substrate conveyer, drivingly rotatable around an axis and comprising a multitude of substrate carriers equidistant from the axis;
More than one vacuum treatment station aligned with the conveying path of the substrate carriers;
At least two of the more than one vacuum treatment stations comprising each a second plasma electrode, the first plasma electrode for the at least two vacuum treatment stations being common for the at least two vacuum treatment stations and being arranged coaxially to the axis.

In one embodiment of the vacuum plasma treatment apparatus according to the invention as just addressed, the more than one vacuum treatment stations comprise at least two magnetron sputter stations with the common first plasma electrode.

In one embodiment of the vacuum plasma treatment apparatus according to the invention as just addressed, the at least two magnetron sputter stations have each a target of silicon.

In one embodiment of the just addressed embodiment of the vacuum plasma treatment apparatus according to the invention, one of the at least two magnetron sputter stations is in flow communication with a reactive gas inlet connected or connectable to a gas reservoir containing hydrogen, the other of the at least two magnetron sputter stations is in flow communication with a reactive gas inlet connected or connectable to a gas reservoir containing oxygen.

In one embodiment of the just addressed embodiment of the vacuum plasma treatment apparatus according to the invention, the substrate conveyer is continuously driven by the drive at least for one 360° rotation and the magnetron sputter sources are continuously sputter-enabled at least during the one 360° rotation.

Two or more of the embodiments as addressed of the vacuum plasma treatment apparatus according to the invention may be combined unless being contradictory.

The invention is, under a further aspect, directed to a vacuum plasma treatment apparatus comprising, within a vacuum recipient, a substrate carrier, at least one first and at least one second plasma electrode for generating a plasma therebetween. The first and second plasma electrodes are connectable to an electric plasma supply source arrangement establishing a first electric potential to the first plasma electrode and a second electric potential to the second plasma electrode, the first and the second electric potentials being both independently variable with respect to a system ground potential. The apparatus further comprises a negative feedback control loop for controlling at least one of the first electric potential, of the second electric potential, of the electric potential difference between the first and the second electric potentials.

In one embodiment of the vacuum plasma treatment apparatus according to the further aspect of the invention, a measured momentarily prevailing entity in the negative feedback control loop consists or comprises one of the first and second electric potentials with respect to a reference electric potential and comprises a sensing element for the respective first or second electric potential with respect to a reference electric potential.

In one embodiment of the vacuum plasma treatment apparatus according to the further aspect of the invention, an adjusted entity in the negative feedback control loop consists or comprises at least one of
a reactive gas flow into the vacuum recipient;
the electric potential difference.

The apparatus further comprises an adjustable flow controller for the reactive gas flow into the vacuum recipient and/or an adjustable plasma power supply arrangement for the electric potential difference between the first and the second plasma electrodes.

The invention is further directed to a method of treating a substrate in a vacuum atmosphere or of manufacturing a treated substrate, with the help of a plasma generated between a first and a second plasma electrode, comprising providing at at least one of the first and of the second plasma electrodes first surface areas -NPL- being, during the treating, predominantly coated and second surface areas -PL- being predominantly sputtered off, thereby selecting a ratio Q of the sum of the second surface areas to the sum of the first surface areas, both projected on an envelope-locus of the respective plasma electrode to be:
0.1≤Q≤9.

In one variant of the method according to the invention, the ratio Q is selected to be:
0.4≤Q≤1.

One variant of the method according to the invention, comprises electrically supplying the first and the second plasma electrodes on independently variable electric potentials.

Variants of the method according to the invention are performed by means of the vacuum treatment apparatus according to the invention or by means of one or more than one of its embodiments.

The invention shall now be further exemplified with the help of figures.

The figures show:

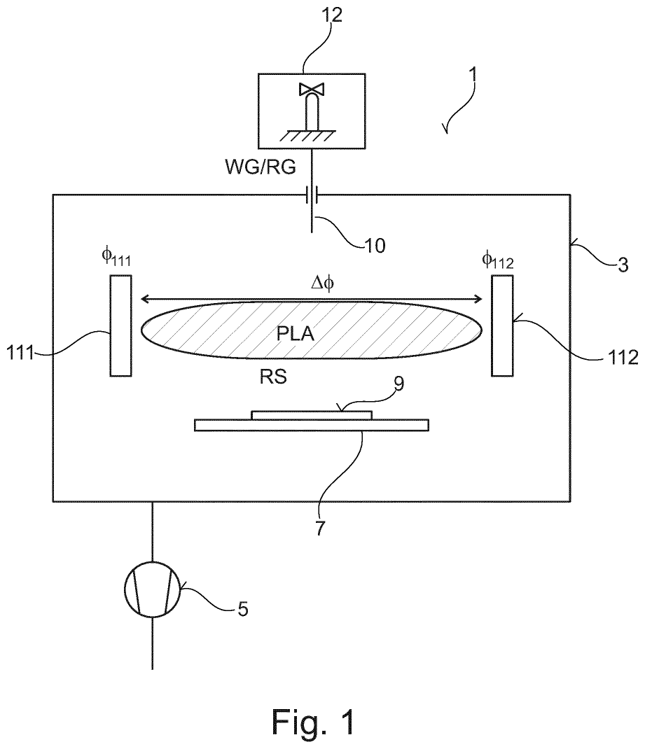

FIG. 1: most schematically and simplified, a vacuum plasma treatment apparatus, as addressed in context with the present invention, under a most generic aspect;

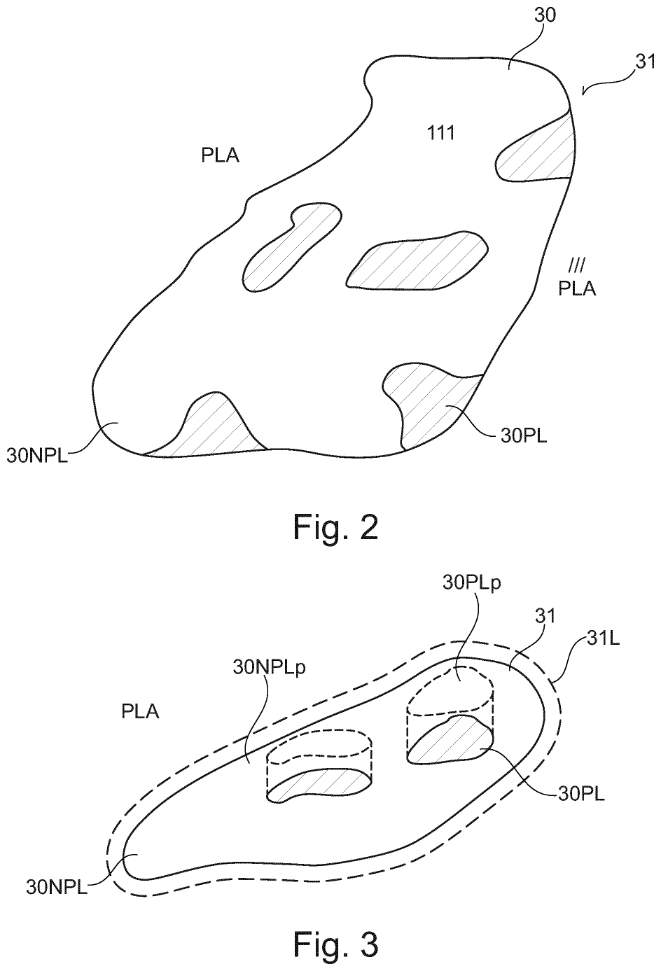

FIG. 2: most schematically and simplified, a cutout of a first plasma electrode according to the principle of the apparatus according to the invention;

FIG. 3 a representation according to that of FIG. 2, to explain how different surface areas of the surface of a first plasma electrode of an apparatus according to the invention are to be brought in mutual relation;

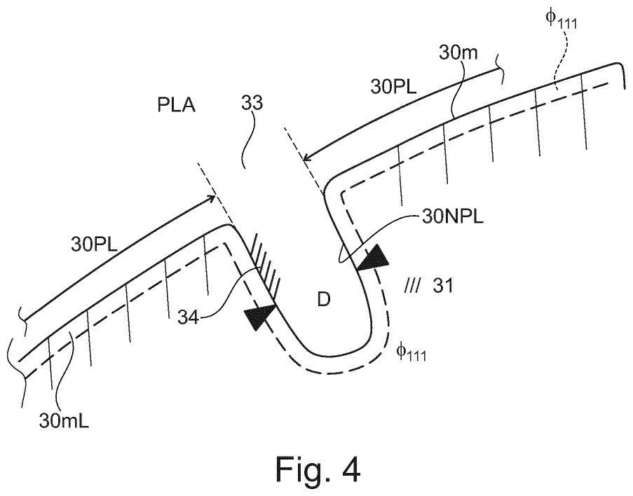

FIG. 4: most schematically and simplified, a cross-sectional representation of a cutout of the surface pattern of a plasma electrode in an apparatus according to the invention;

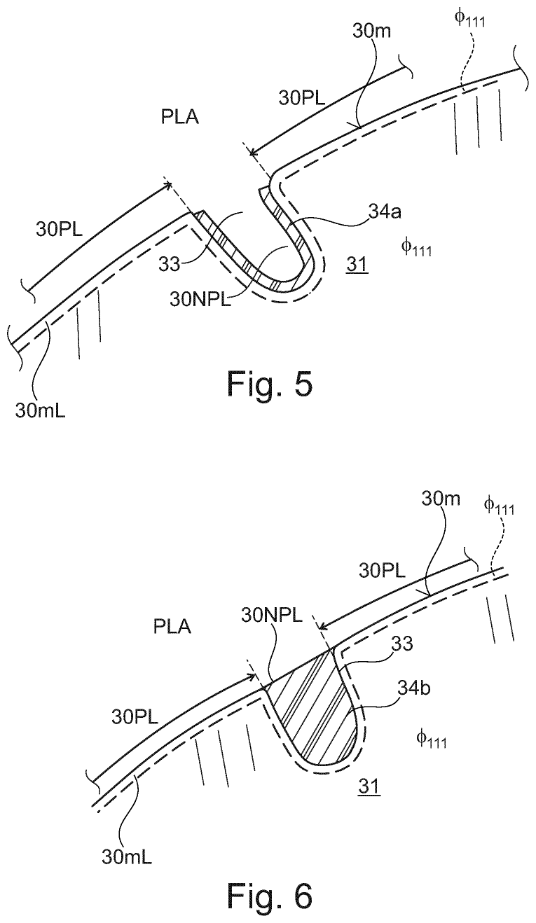

FIGS. 5 to 8: respectively and in representations in analogy to that of FIG. 4, cutouts of embodiments of the surface pattern of a plasma electrode in respective apparatus according to the invention;

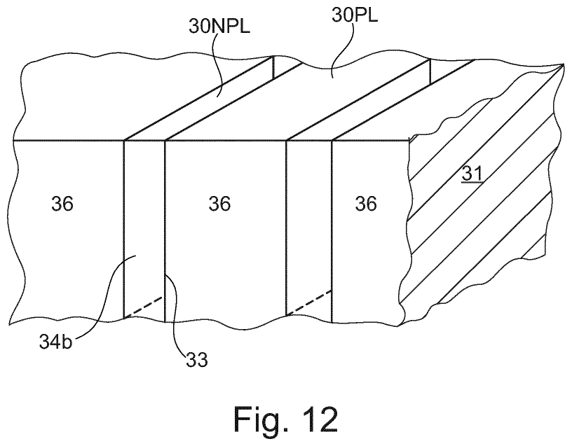

FIGS. 9 to 12: Schematically and simplified, and in perspective representations, cutouts of embodiments of a plasma electrode in respective apparatus according to the invention;

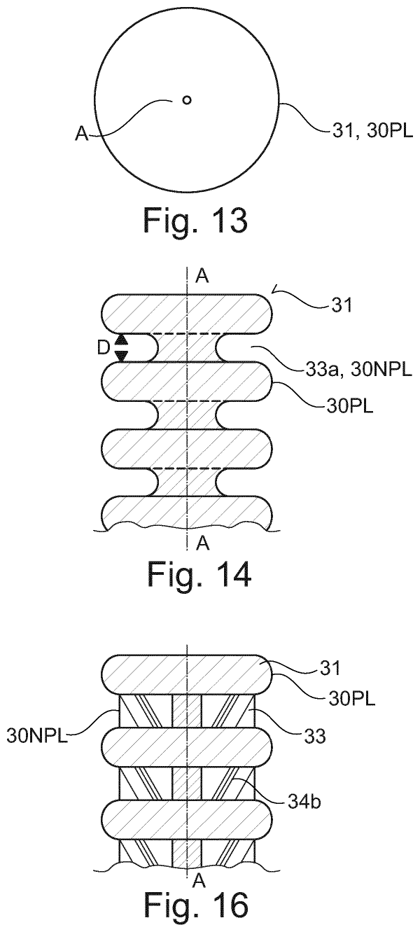

FIG. 13: schematically, a top view on an embodiment of a plasma electrode in an apparatus according to the invention;

FIG. 14: a crossectional representation of a cutout of a plasma electrode in an apparatus according to the invention;

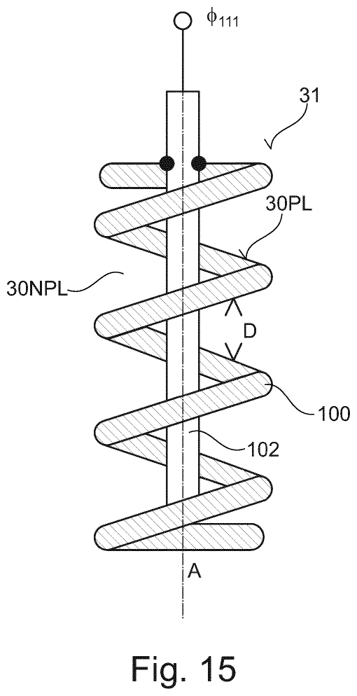

FIG. 15: in a schematic, perspective representation, an embodiment of a plasma electrode in an apparatus according to the invention; FIG. 16: a crossectional representation of a cutout of an embodiment of a plasma electrode in an apparatus according to the invention;

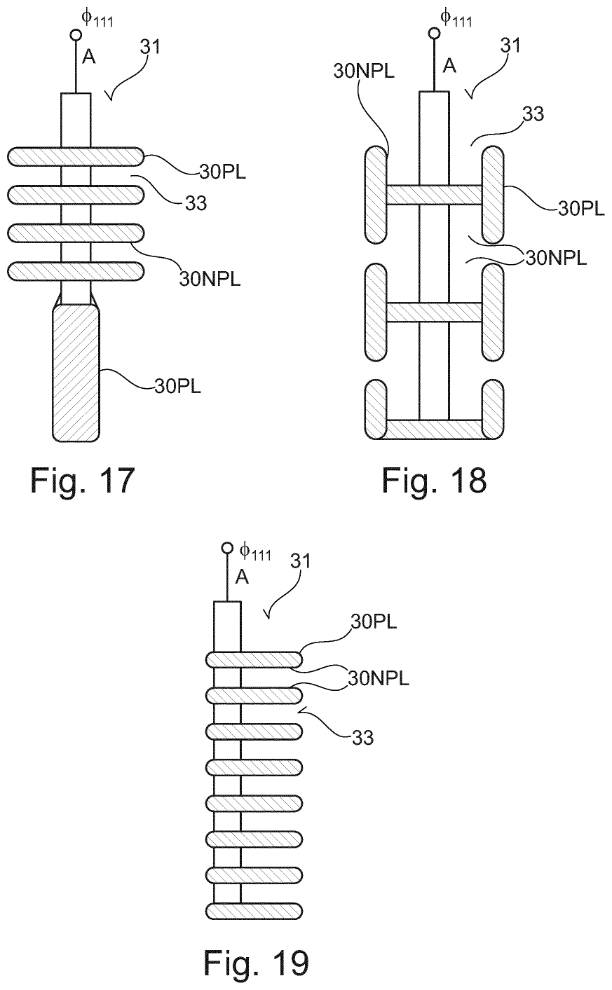

FIGS. 17 to 19: schematically, cross-sectional representations of embodiments of plasm electrodes in respective apparatus according to the invention;

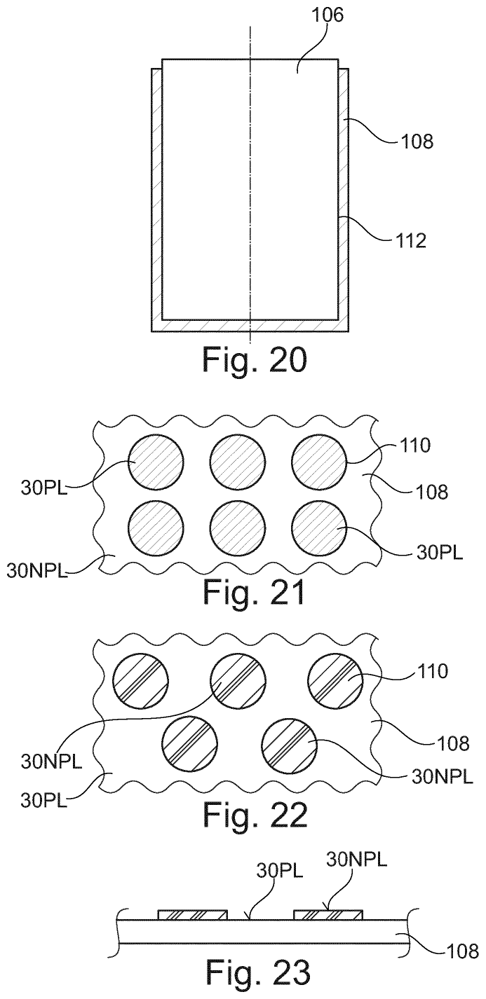

FIG. 20: schematically, the principle of embodiments of plasma electrodes in apparatus according to the invention, whereat the surface of a plasma electrode is realized by means of an envelope;

FIG. 21 to 23: cutouts of the envelope according to FIG. 20 defining respective surface patterns of embodiments of the plasma electrode in respective apparatus according to the invention;

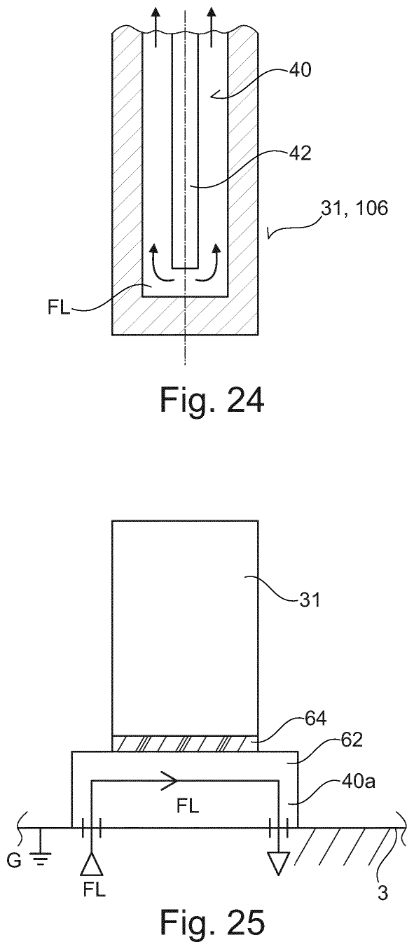

FIG. 24: schematically and simplified, a cutout of an embodiment of a plasma electrode being cooled, in an apparatus according to the invention;

FIG. 25: schematically and simplified, a further embodiment of a plasma electrode being cooled in an apparatus according to the invention;

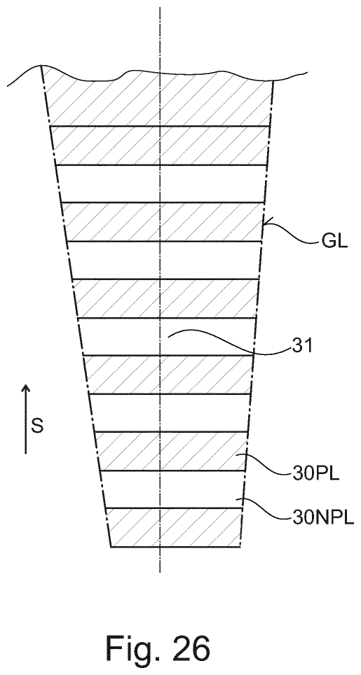

FIG. 26: simplified and schematically, an embodiment of a plasma electrode with a tapering cross-section in an apparatus according to the invention;

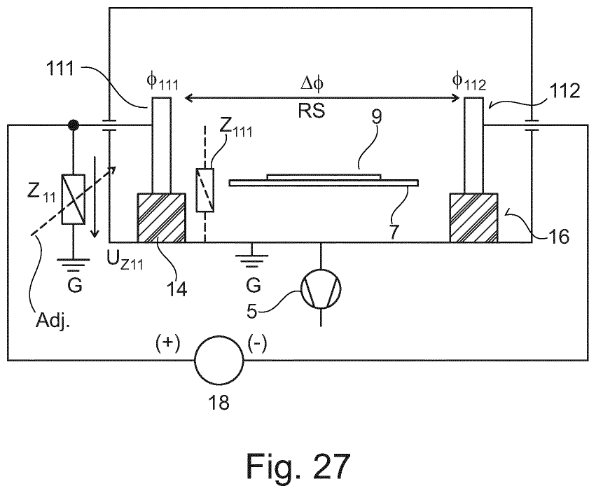

FIG. 27: schematically and simplified the electric operation of and the respective members in an embodiment of the apparatus according to the invention;

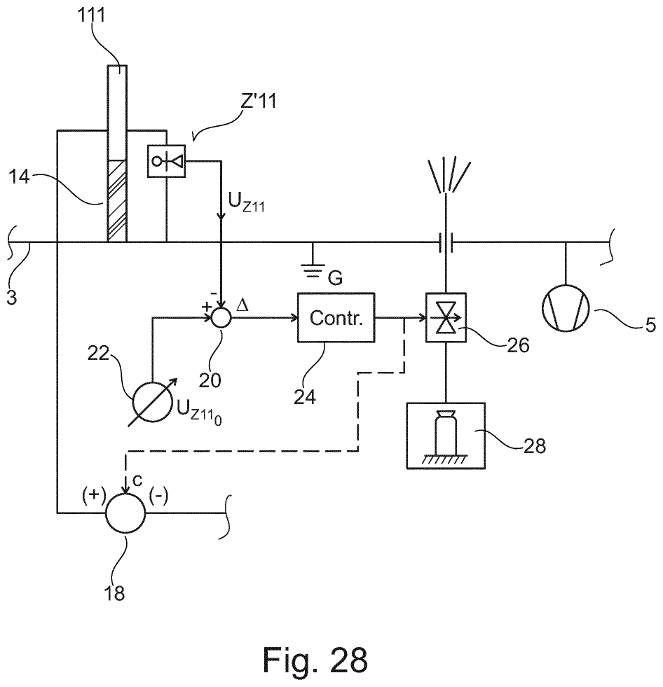

FIG. 28: schematically and simplified and as a cutout in a representation in analogy to that of FIG. 27, a negative feed-back control of an electric potential at one of the plasma electrodes in an apparatus according to the invention;

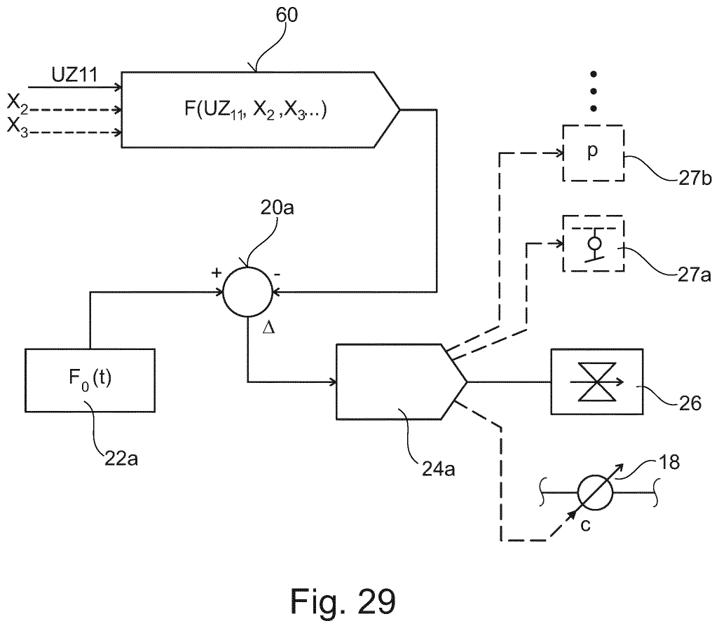

FIG. 29: most generically and simplified a negative feed-back control of the electric potential at one of the plasma electrodes in an apparatus according to the invention;

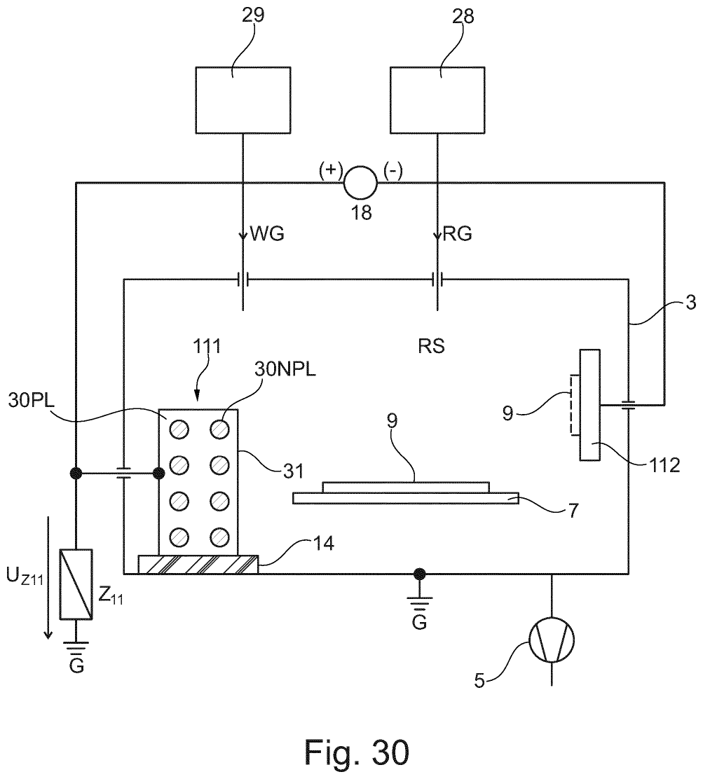

FIG. 30: In a representation in analogy to that of FIG. 27, an embodiment of an apparatus according to the invention, whereat one of the plasma electrodes is target of a sputter source or a workpiece carrier of an etching source;

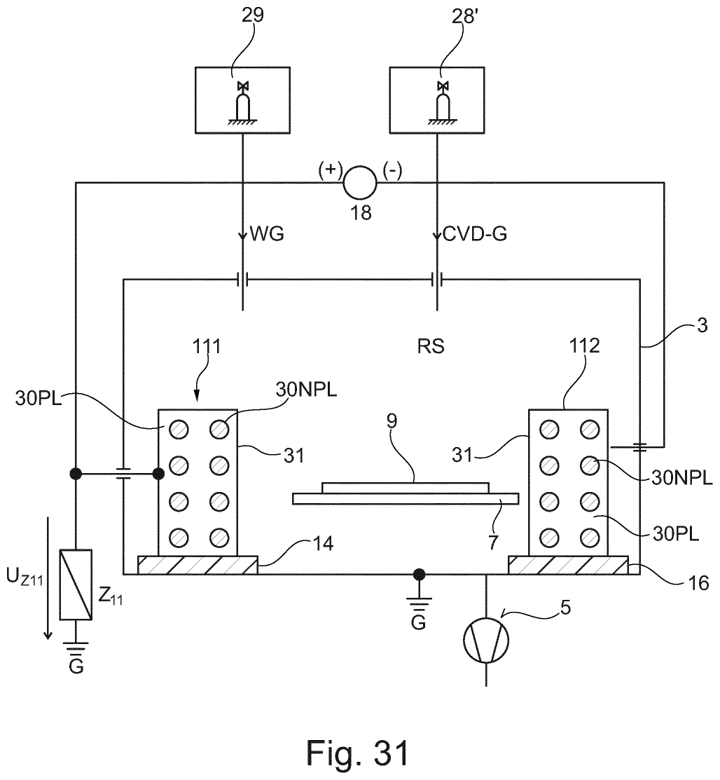

FIG. 31: In a representation in analogy to that of FIG. 30, an embodiment of an apparatus according to the invention with two at least similar plasm electrodes;

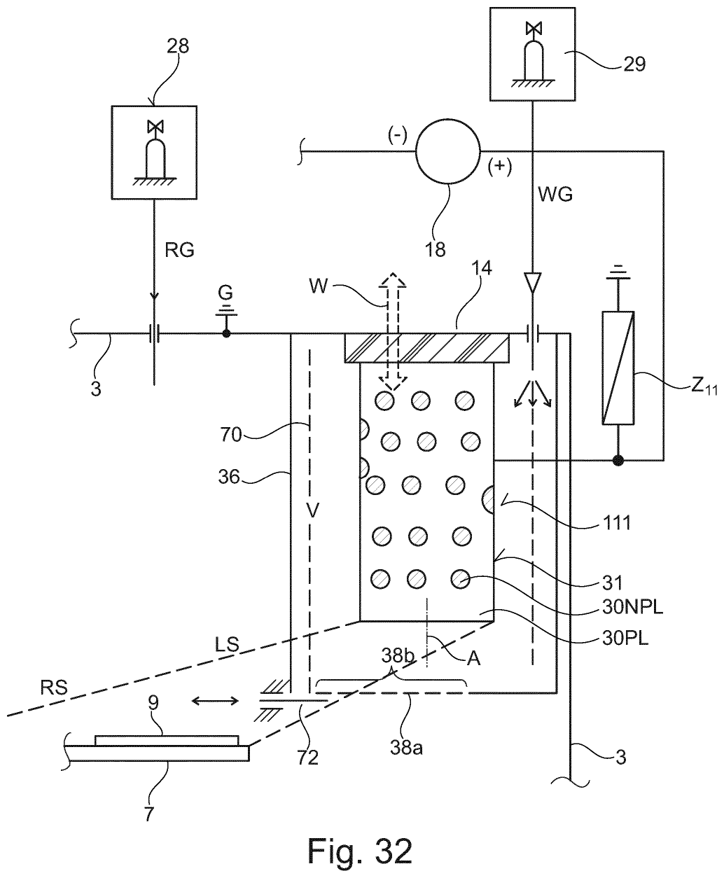

FIG. 32: in a representation in analogy to that of FIG. 31, a cutout of an embodiment of the apparatus according to the invention;

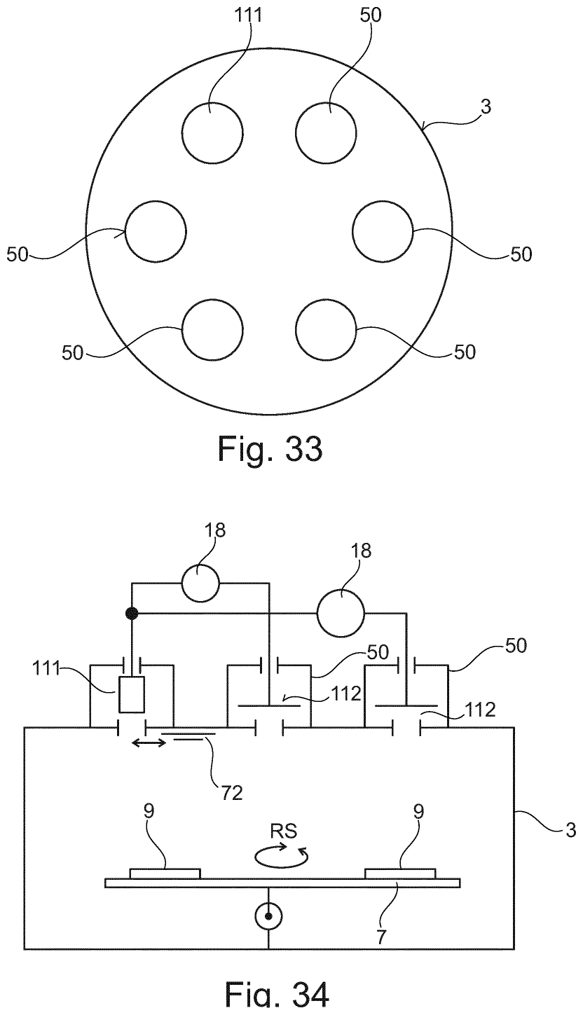

FIG. 33: most schematically and simplified a top view on an embodiment of the apparatus according to the invention;

FIG. 34: most schematically and simplified I side view on the embodiment according to FIG. 33;

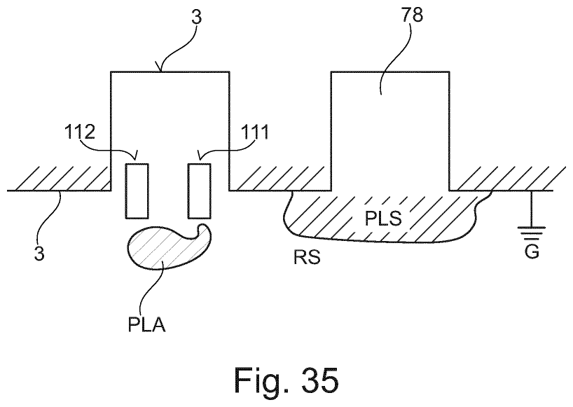

FIG. 35: most schematically and simplified a cutout of an embodiment of the apparatus according to the invention showing decoupling different plasmas.

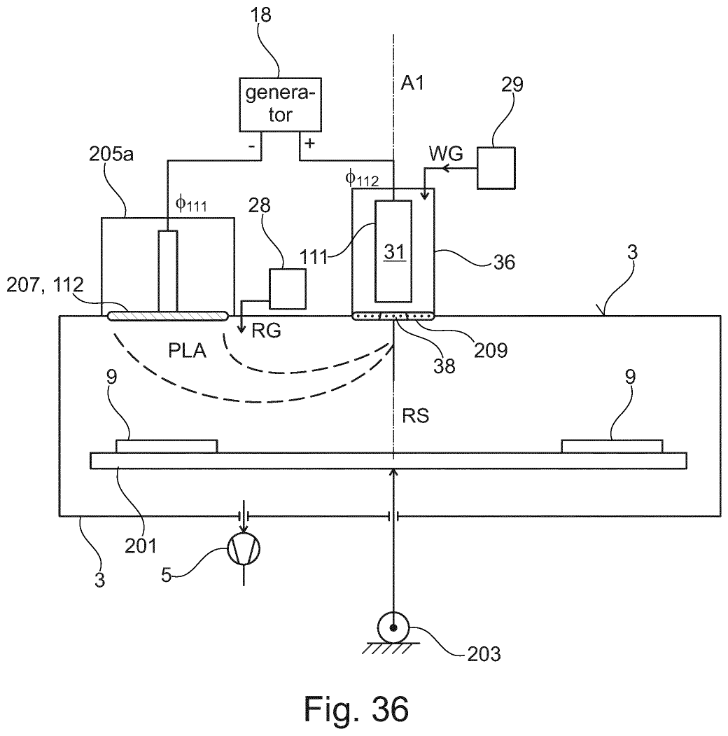

FIG. 36: in a representation in analogy to that e.g. of FIG. 34 an embodiment of the apparatus according to the invention;

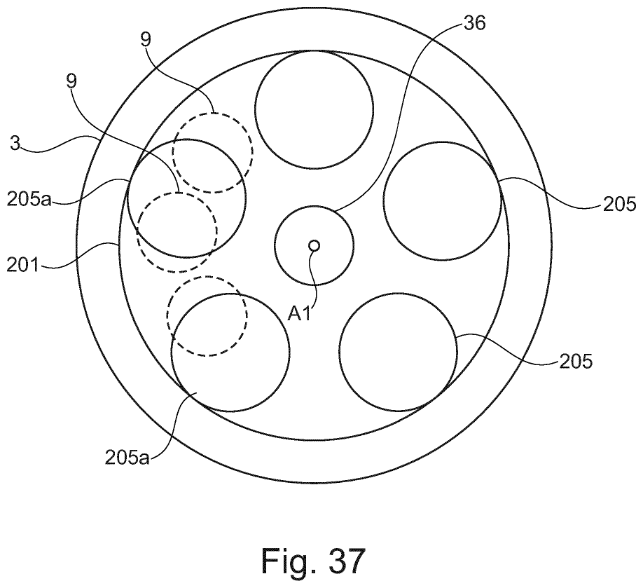

FIG. 37: most schematically and simplified the embodiment of FIG. 36 in a top view;

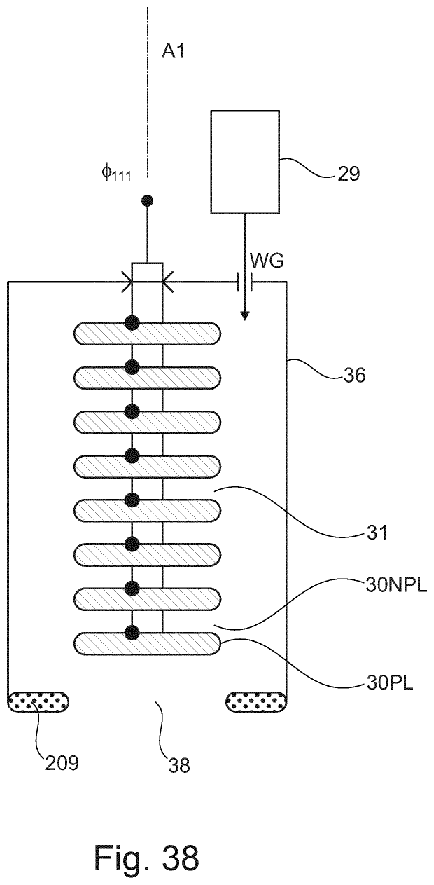

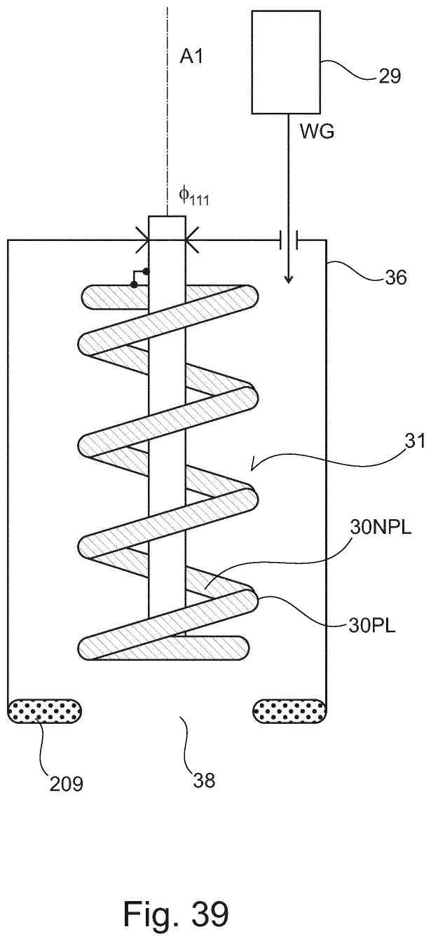

FIGS. 38 to 41: schematically, respective embodiments of plasma electrodes in a housing as of respective apparatus according to the invention, especially according to FIGS. 36 and 37;

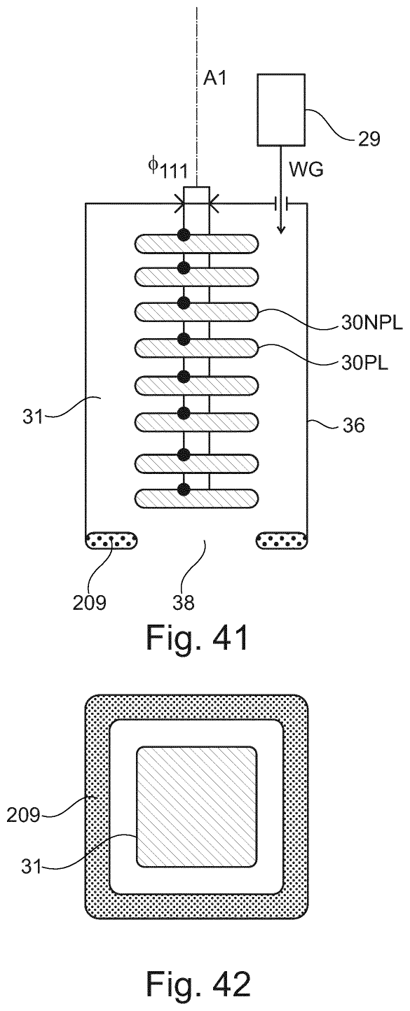

FIG. 42: schematically a cross-sectional representation of the plasma electrode according to FIG. 41;

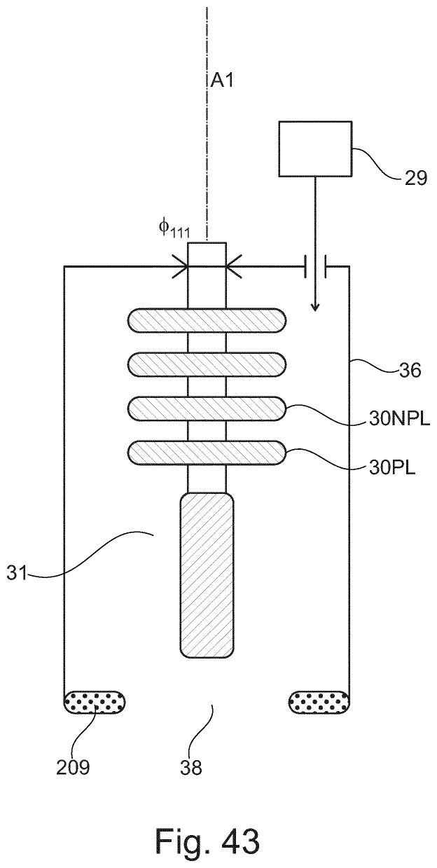

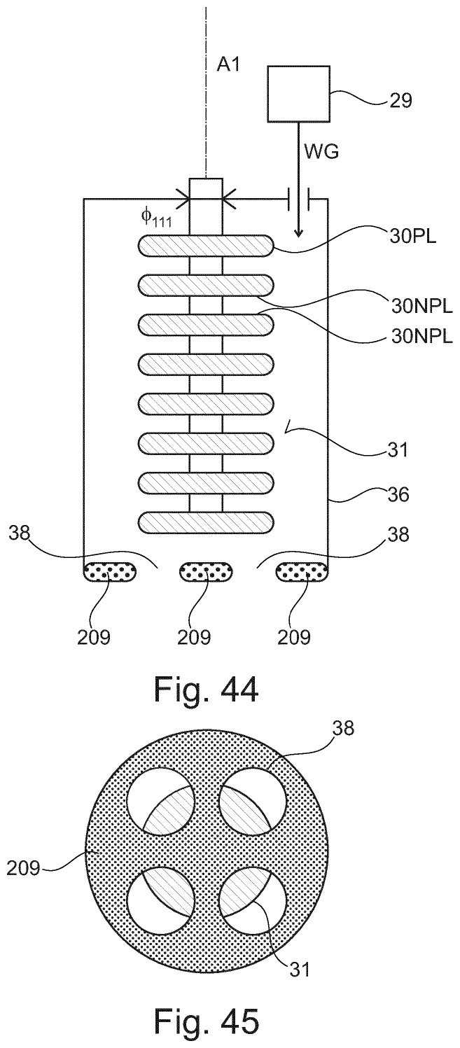

FIG. 43 and 44: schematically, respective embodiments of plasma electrodes in a housing in respective apparatus according to the invention, especially according to FIGS. 36 and 37;

FIG. 45: schematically, a cross- sectional representation of the plasma electrode according to FIG. 44;

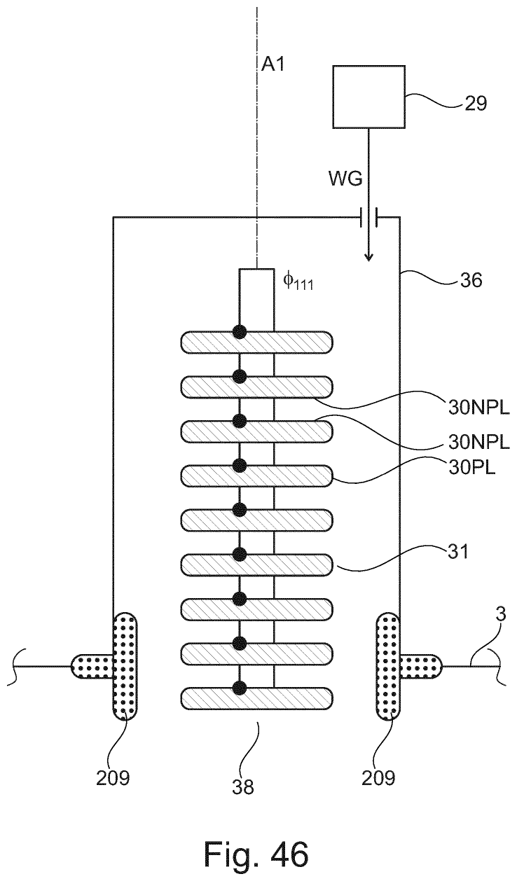

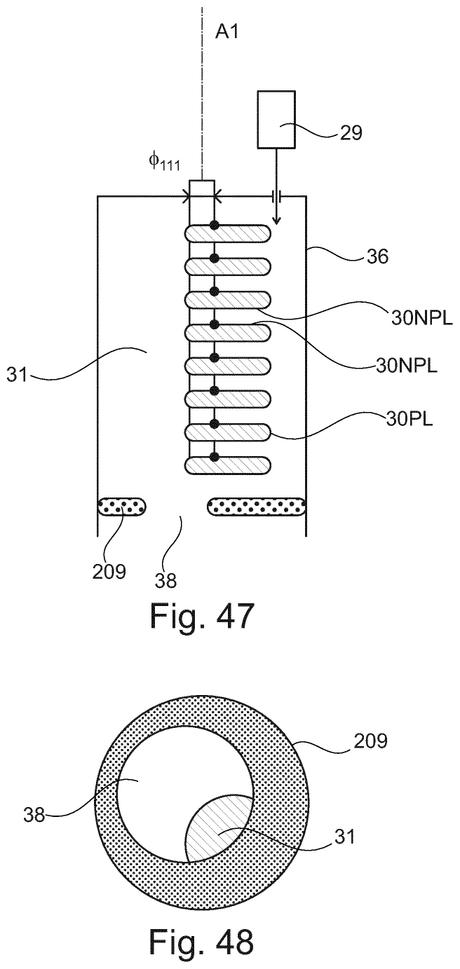

FIG. 46 and 47: schematically, respective embodiments of plasma electrodes in a housing in respective apparatus according to the invention, especially according to FIGS. 36 and 37;

FIG. 48: schematically, a cross-sectional representation of the plasma electrode according to FIG. 47;

FIG. 1 shows most schematically and simplified, a vacuum plasma treatment apparatus, also called arrangement, as addressed in context with the present invention under a most generic aspect.

The vacuum plasma treatment apparatus 1 comprises a vacuum recipient 3, operationally connected to a pumping arrangement 5. A substrate carrier 7 for one or more than one substrate 9 is provided, stationary or drivingly movable in the vacuum recipient 3. The substrate carrier 7 may be operated in electrically floating manner or on an electric reference potential or may be operated on a desired bias potential. The one, or more than one, substrate 9, is exposed to a plasma PLA which is generated between a first plasma electrode 111 and a second plasma electrode 112. A working gas WG and/or a reactive gas RG is fed through a gas feed line arrangement 10 to the vacuum recipient 3. The gas feed line is in flow connection with a respective reservoir arrangement 12 containing the respective gas.

By means of an electric plasma supply source arrangement (not shown in FIG. 1) there is established a plasma driving electric potential difference Δϕ between respective electrode potentials ϕ111 and ϕ112 at the respective electrodes 111 and 112.

We now address the first electrode 111 as defined above. This first electrode 111 has customarily, a surface of a metallic material e.g. of a metal. During some plasma treatment processes, material having a lower electric conductivity than the metallic material of the surface of electrode 111 is generated in the reaction space RS, and deposits on the first electrode 111.

As examples and as was already addressed above:

If the plasma treatment is sputter deposition by magnetron- or non-magnetron sputtering, then the second electrode 112 comprises a consumed sputter target. If the material of the target is electrically less conductive than the metallic material of the surface of a customarily used first electrode—the “anode” of the sputter source—or such material is generated by reacting the target material in an atmosphere containing a reactive gas, deposition of such material which is electrically less conductive than the metallic material of the surface of the customarily used first plasma electrode 111, on the first electrode destabilizes the sputtering process.

If the plasma treatment is substrate-etching, then such material of relatively low electric conductivity may be the material sputtered off the substrate (etched) or may result from such etched off material reacted with a reactive etching gas fed to the reaction space RS.

Also, material to be deposited on the substrate 9 resulting from chemical reaction of gases in the plasma PLA, may be electrically less conductive than the metallic material surface areas of the first and of second customarily used plasma electrodes.

In any case of the presence of material which has a lower electric conductivity than the metallic material of the surface of the customarily used first electrode 111, the metallic material surface areas of the first electrode 111 become coated with that material. This phenomenon, destabilizes the plasma treatment process, e.g. by long time drifting, is known in the art and addressed e.g. as “electrode hiding”, “buried electrode”, “vanishing” electrode etc. and shall be reduced or even avoided by respective tailoring of the first plasma electrode different from the addressed customarily used first electrodes 111 and according to the invention.

As another example at customarily used plasma electrodes:

If the vacuum plasma treatment process is operated with a Rf plasma, the surface also of the first plasma electrode may be the dielectric material surface of a dielectric material layer deposited on a metallic material base of the first plasma electrode. Such dielectric layer provides for capacitive coupling of the Rf supply to the plasma. If the process generates deposition material which as well is dielectric, deposition of this material on the dielectric surface of the first electrode changes the capacitive coupling which as well may destabilize the process.

Thus, and in other words, it is known in the art of vacuum plasma treatment, that all plasma electrode surfaces are simultaneously sputtered off and coated. On a target, as a second plasma electrode, sputtering i.e. freeing material from the target surface, is predominant, but “redeposition” of material from the reaction space on the target does not vanish. In reactive sputtering, i.e. sputter deposition of a layer on a substrate, especially if the deposited material is electrically less conductive than the target material, “redeposition” on the target surface may lead to so-called “target poisoning”.

The first plasma electrode as we have defined it above is predominantly exposed to poisoning deposition rather than to sputtering.

The inventors of the present invention have recognized, that specific tailoring the surface of the first plasma electrode 111, leads to self-cleaning of a part of the surface, rapidly after plasma ignition, and thus prevents destabilizing the plasma treatment process by the first plasma electrode 111 becoming buried.

This is generically and astonishingly established by tailoring the surface of a body of the first plasma electrode 111, so, that along first areas of that surface plasma may not burn and along the remaining second areas of that body plasma does burn. Predominantly along the first surface areas material which is possibly less electrically conductive than metallic material of the second surface areas of the body deposits. The second surface areas are predominantly sputtered, establishing and maintaining a metallic material surface contact to the plasma, or, more generically, maintain their initial characteristic be it of metallic material or of defined capacitive coupling.

Thus, one may say that the surface of a body of the first plasma electrode 111 is patterned by first surface areas which do not contribute to the electrode effect and second surface areas which do contribute to the electrode effect.

FIG. 2 shows most generically a part of a surface 30 of a body 31 of the first plasma electrode 111 according to the invention. Along surface areas 30NPL plasma PLA is prevented to burn whereas the plasma PLA does burn along the remaining surface areas 30PL.

FIG. 3 shows again the body 31 of the first plasma electrode 111 with the first surface areas 30NPL and the second surface areas 30PL. The body 31 is surrounded by a geometric locus envelope 31L. The ratio Q of the sum of the projections 30PLp of the second surface areas 30PL on the geometric locus envelope 31L and the sum of the projections 30NPLp of the first surface areas 30NPL on the geometric locus envelope 31L is thereby selected to be
0.1≤Q≤9

and thereby in a today practiced embodiment:
0.4≤Q≤1.

The surface areas 30PL are of a metallic material or are of dielectric material of a dielectric material layer deposited on a metallic material base of the body 31.

According to FIG. 4 the surface areas 30NPL are formed by void recesses 33 in the metallic material surface 30m of the body 31. The metallic material surface 30m may be the surface of a metallic material body 31 or the surface of a metallic material layer as shown schematically in dash line at 30mL. The metallic material surface 30m/30mL is operated on the first electric potential Φ111.

The recesses 33 are dimensioned so as to prevent the plasma PLA to burn therein, thus, as the skilled artisan knows, with a minimum cross-sectional extent D rather smaller than twice the prevailing darkspace distance. Exposed to the plasma PLA only the surfaces of the recesses 33, as first surface areas 30NPL, become coated with the material generated by the vacuum plasma treatment process, which may be of relatively low electric conductivity, less electrically conductive than the metallic material of the surface 30m. In opposition thereto, the metallic material surface areas 30PL are increasingly sputtered.

Heuristically these phenomena may be explained as follows:

In the metallic material surface recesses 33 no plasma burns as they are dimensioned with an opening minimum diameter smaller than two times the dark space distance. No darkspace is present adjacent the recess surfaces. Therefore, no electric potential difference accelerates charged particles towards the recess surface. These particles just deposit in the recesses 33. As no plasma is present in the recesses 33 conductivity is relatively low and the electric field as well as the current between the first and second plasma electrodes concentrates more and more on the outer, metallic material areas 30PL. There, with a prevailing dark space and high conductivity, charged particles are increasingly accelerated towards the surface and sputter the surface areas 30PL, preventing a net deposition of the relatively low conductive material there.

Nevertheless, buildup over time of the coating in the recesses 33 and respective increase of sputtering at the surface areas 30PL still leads to some drifting of the process.

This led the inventors to pre-apply surface areas 30NPL of electrically insulating material, as of a ceramic material, thereby establishing stable initial conditions just from the beginning of processing.

According to the embodiment of FIG. 5 the void recesses 33 in the metallic material surface 30m of the body 31 are pre-coated with a dielectric material coating 34a, e.g. of a ceramic material.

According to the embodiment of FIG. 6 the recesses 33 in the metallic material surface 30 of the body 31 or with a metallic material coating 30mL thereon are filled with a dielectric material e.g. with a plug 34b, e.g. of a ceramic material.

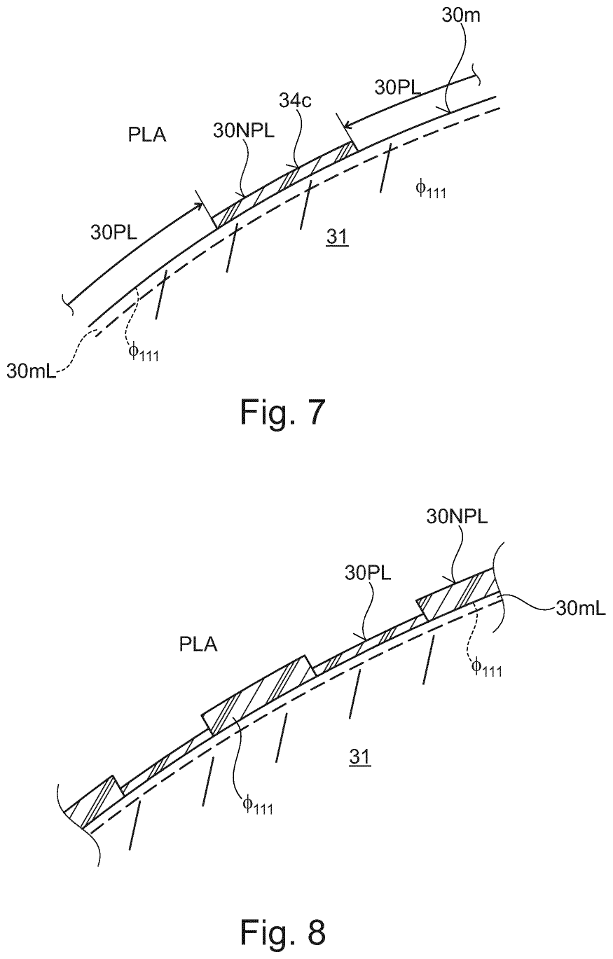

According to the embodiment of FIG. 7, the metallic material surface 30 of the body 31 is precoated with areas or “isles” 30NPL of dielectric material, e.g. with a layer 34c of ceramic material.

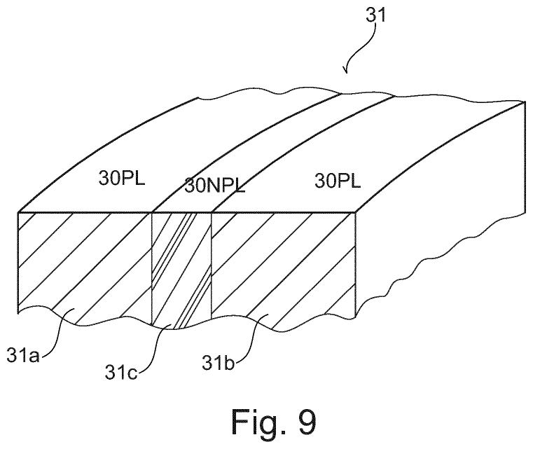

With an eye on FIG. 7, FIG. 8 shows again schematically the pattern of the surface of the first plasma electrode 111 as applicable for Rf plasma. Here the second surface areas 30PL as well as the first surface areas 30NPL are surface areas of respective layers of dielectric materials. The dielectric material and the thickness of that layers which form the second surface areas 30PL provide for a much higher coupling capacity then the dielectric material and the thickness of those layers which provide for the first surface areas 30NPL.

Please note that also when the second surface areas 30PL are realized with dielectric material layers, the first surface areas 30NPL might be realized according to the FIGS. 4 to 6.

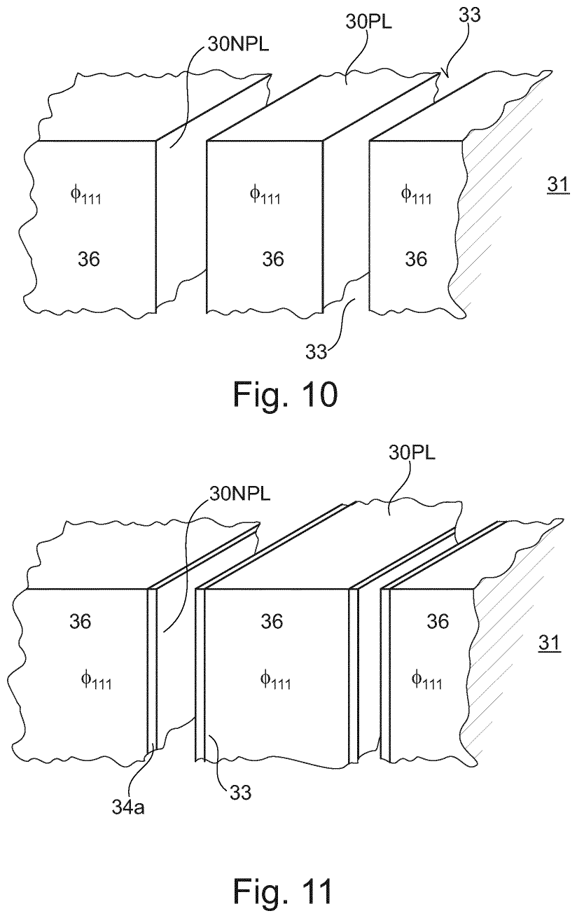

According to the embodiment of FIG. 9 the body 31 is split in multiple parts 31a and 31b . . . and interlayers 31c of dielectric material are sandwiched between two subsequent parts 31a, 31b which are either of metallic material or are—30mL—coated with a metallic material layer. The metallic material parts are electrically interconnected (not shown in the figure) and are operated on the first electric potential Φ111.

Whereas FIG. 4, 5 and 6 show recesses which have rather the shape of holes, FIGS. 10 to 12 shows recesses 33 realized as interspaces between plate-shaped webs 36 of metallic material or coated with layers of metallic material.

FIGS. 13 to 16 show, more specifically, embodiments of the electrode body 31 of the first plasma electrode 111. According to FIG. 13 which shows a top view on a body 31, the body 31 extends along an axis A. Although the axis might be curved, in today realized embodiments the axis A is straight.

Further and in spite that the top view shape of the body 31 according to FIG. 13 is circular, it might also be e.g. elliptical or polygonal.

According to the embodiment of FIG. 14 the body 31 is of metallic material or is coated with a layer of metallic material and comprises recesses 33a realized by grooves 33a around the axis A. Thus, the embodiment of FIG. 13 accords with the generic embodiment of FIG. 4. Please note, that the multiple grooves 33a may be replaced by one or more than one helical groove (not shown in the figure) around the axis A and along the body 31. Clearly all generic forms of the first surface areas 30NPL according to the FIGS. 4 to 8 may be realized as a helically extending surface area around the axis A, resulting in a second surface area 30PL which is helically as well.

The second surface areas 30PL in FIG. 14 may be realized by spaced, distinct metallic material plates or plates which are coated with a metallic material layer and which are electrically interconnected and operated on the first electric potential Φ111.

FIG. 15 shows an example of the body 31 of the first plasma electrode 111 in which the second surface area 30 PL is helically wound around the straight axis A. Thereby the second surface area is realized along a helically wound wire 100. The second surface area 30PL is predominantly defined along the outer periphery of the wire 100. The distance between neighboring turns of the helix is D, and possibly also the radial distance from the central feed 102 to the inner periphery of the helix to be at most D. The helix is stand alone with the exception of being electrically connected to the central feed 102. Please note that in the drawing the hatching does not indicate a cross-section.

For processing pressures as customary used for sputtering, the distances D as also shown in FIG. 14 was selected to be in the range of
1 mm≤D≤110 mm, especially of 7 mm≤D≤15 mm.

The embodiment of FIG. 16 is similar to the embodiment of FIG. 14, whereby the recesses or interspaces 33a as of FIG. 14, are neither void, nor coated with a dielectric material layer as of generic embodiments of FIG. 4 or 5, but are filled by dielectric material, e.g. by dielectric material plates according to 34b in analog to FIG. 6. FIG. 17 to 19 show further embodiments of the body 31 of the first anode 111, all along the straight axis A. Please note that in these drawings too the hatching does not indicate a cross-section.

FIG. 20 shows, schematically, an embodiment of the body 31, as an example extending along the axis A. the body 31 comprises a core 106 and an envelope 108, which defines the pattern of first surface areas 30NPL and of second surface areas 30PL as becomes apparent in context with the FIGS. 21 to 23.

According to FIG. 21 the envelope 108 has a pattern of void openings 110, through which, once applied to the core 106 with a metallic material surface, the second surface areas 30PL are freely accessible. The envelope 108 per se is of a dielectric material.

According to FIG. 22 the envelope 108 has a pattern of void openings 110, through which, once applied to the core 106 with a dielectric material surface, the first surface areas 30NPL are freely accessible. The envelope 108 per se is of a metallic material.

According to FIG. 23 the metallic material envelope 108 carries the pattern of first surface areas 30NPL and may be applied to the core 106 irrespective of the core material. Inversely the envelope 108 may be of a dielectric material and carry the pattern of second surface areas 30PL (not shown in the figures).

The envelope 108 may be a maintenance replacement part and thus easily exchangeable on the core 106.

The skilled artisan recognizes now a huge number of variants to realize the surface pattern of the body of the first plasma electrode 111 according to the invention and according to his specific requirements.

All embodiments of the body 31 may be cooled which may be realized by means of a cooling fluid led trough the body 31 or by mounting the body to a heat sink member.

According to the embodiment of FIG. 24 there is provided centrally and along the axis A of a metallic material body 31 or core 106 of the body 31 a coaxial channel bore 40. A cooling fluid tube 42 extends along the bore 40 and discharges cooling fluid FL at the bottom of channel bore 40. The cooling fluid FL is discharged from the channel bore 40 at the one end of the body 31 or core 106 (not shown in the figure).

According to the embodiment of FIG. 25, the metallic material body 31 or core 106 is mounted to a heat sink member comprising a channel arrangement 40a through which a cooling fluid FL is flown. Providing between the body 31 or core 106 and the heat sink member 62 a member or interlayer 64 of an electrically isolating material and being thermally well conductive, as e.g. of AlN allows to operate the heat sink member on the system ground potential G thermally narrowly coupled to the body 31, latter nevertheless being electrically isolated from system ground.

According to FIG. 26 the body 31, in any form of realization, but especially according to the embodiment of FIGS. 13 to 19, is enclosed by a geometric locus GL, as a geometric envelope, which tapers considered in at least one direction S as along the axis A. Especially in dependency of the mounting location of the first electrode 111 in the vacuum recipient 3, by such local or overall tapering, the distribution of the coating/sputtering effect along the body 31 may be controlled and especially be homogenized.

We now describe how the first and second plasma electrodes are electrically operated in embodiments of the apparatus according to the invention.

As shown in FIG. 27, and as a part of the present invention, both electrodes 111 and 112 are electrically operated so, that the respective electrode's electric potentials ϕ111 and ϕ112 may vary in a mutually independent manner with respect to a system ground potential G applied to the vacuum recipient 3. The first plasma electrode 111, as well as the second plasma electrode 112 are operated in an electrically isolated manner shown by isolators 14 and 16. A floating plasma power supply source arrangement 18 is operationally connected to the plasma electrodes 111 and 112 and applies between the first and second plasma electrodes the potential difference A. The plasma power supply source arrangement 18 may be tailored to generate at least one of DC, pulsed DC, HIPIMS, AC up to RF.

The substrate carrier 7 may be electrically operated in a floating manner, on system ground potential G or on a bias potential (not shown in FIG. 27) which may be DC, AC up to RF. Please note that if etching is performed, the substrate carrier 7 may be realized by the second plasma electrode 112. Under consideration of the low plasma impedances from the plasma electrodes 111 and 112 to system ground G, the electrodes 111 and 112 may freely assume the respective electric potentials ϕ111 and ϕ112, thereby maintaining the potential difference Δϕ as established by the plasma supply source arrangement 18. Thereby and in opposition to making use of the grounded metal wall of the vacuum recipient 3 as first plasma electrode, the first plasma electrode 111 according to the invention and as was described above with multiple embodiments, becomes locally well-defined as the current path from any second plasma electrode to the first electrode 111 loads the first plasma electrode 111 with a current concentrated on the second surface areas -PL- of the surface pattern.

The first electrode 111 may be connected to a reference electric potential, e.g. to system ground potential G via an impedance element Z11 (see also FIG. 30), which appears in parallel to the plasma impedance 2111 and is selected so, that it does practically not influence the overall parallel impedance Z111//Z11. In the realization form as practiced today the impedance Z11 is realized by a resistive element R wherein there is valid
50Ω≤R≤250kΩ,

thereby, in one embodiment, R=1 kΩ.

The impedance element Z11 may be realized by means of at least one passive electronic element and/or by means of at least one electrically active element, e.g. a diode and/or at least one active, electrically controllable element, e.g. a FET. By adjusting the impedance element Z11 as addressed in dash line at Adj in FIG. 27, the self-cleaning effect of the second surface areas -PL- of the surface pattern of the first electrode 111 may be tuned.

Further providing the impedance element Z11 may improve ignition of the plasma PLA and may be used, as addressed later, for sensing the electric potential ϕ111 with respect e.g. to system ground potential G.

According to FIG. 28 a sensing element Z11′ is provided sensing the momentarily prevailing electric potential ϕ111 of the first plasma electrode 111 with respect to a reference electric potential, as of system ground potential G. E.g. the voltage UZ11 across impedance element Z11 (FIG. 27) may be sensed. The respective voltage UZ11 is indicative of and exploited as measured controlled signal in a negative feedback control loop for the controlled signal UZ11. As an adjusted entity the flow of a reactive gas is adjusted and/or the output signal of the plasma supply source arrangement 18, as shown in dash line. Thus, the measured controlled signal UZ11 is compared at a difference forming unit 20 with a preset value UZ11ₒ for the controlled signal, set at unit 22. The control deviation signal A at the output of difference forming unit 20 is led via a controller 24, to a flow adjusting valve 26 adjusting the flow of a reactive gas or gas mixture from a reactive gas reservoir 28 containing such reactive gas or gas mixture into the vacuum recipient 3. Additionally or alternatively the control deviation signal A acts on a control input C of the plasma supply source arrangement 18.

FIG. 29 shows schematically and simplified a functional block/signal-flow representation of the more generalized negative feed-back control loop explained in context with FIG. 28.

The voltage UZ11 as sensed according to FIG. 28 is fed to a processing unit 60. The processing unit 60 calculates the momentarily prevailing value of a function of UZ11, F(UZ11) possibly of a multivariable function F (UZ11, X2, X3 . . . ) thereby taking additional input signals X2, X3 . . . into account. The result of processing in the processing unit 60 is the momentarily prevailing value of the function F.

In the preset unit 22a the desired value of function F is set or the desired time course of function F, Fₒ. At the difference forming unit 20a, the momentarily prevailing output signal of processing unit 60 is compared with the constant or time varying desired value Fₒ for function F. The output signal of the difference forming unit 20a acts as control deviation A via controller unit 24a on adjusting valve 26 and/or on the control input C of the plasma supply source arrangement 18 and possibly on additional adjusting members for the plasma treatment process as e.g. on an adjustable substrate bias 27a, process pressure 27b etc.

It is assumed that the negative feedback control as addressed and explained in context with FIGS. 28 and 29 is per se an invention.

In a more generalized approach, by such negative feed-back control loop—per se possibly inventive—at least one of the first electrical potential Φ111 and of the second electrical potential Φ112 and of the potential difference ΔΦ between the first and the second electrical potentials Φ111, Φ112 is controlled to be kept or to follow a respectively preset constant or time varying value.

FIG. 30 shows, most schematically and simplified an embodiment of the vacuum plasma treatment apparatus according to the invention and as discussed up to now. The same reference numbers are used as introduced up to now. Please note, that the impedance Z11 as well as the negative feedback control loop (not shown in FIG. 30) as was just described, are optional.

Reference number 29 addresses a working-gas reservoir, e.g. containing argon, by which a working gas WG is fed into the vacuum recipient 3, alternatively or additionally to a reactive gas RG from a reactive gas reservoir 28. The second plasma electrode in this embodiment may be a substrate carrier for a substrate 9, shown in dash line and the vacuum plasma treatment process may be etching of that substrate 9.

Up to now we have predominantly addressed a plasma treatment in which the second plasma electrode 112 is primarily consumed, and the first plasma electrode 111 is realized according to the present invention. Both plasma electrodes 111, 112 are electrically supplied according to the present invention e.g. as shown and addressed in context with FIG. 27.

In some applications, as in PECVD, none of the plasma electrodes is to be consumed and none of these electrodes should become buried or hidden by a covering of material especially of material less electrically conductive than the metallic material surface of the respective plasma electrode.

In such cases or applications both electrodes 111 and 112 may be constructed according to the present invention but must not necessarily be equal. This is shown schematically and simplified in FIG. 31.

The same reference numbers as introduced up to now are used. No additional explanations are needed. The gas reservoir 28′ for PECVD processing contains a gas, CVD-G, which is chemically reacted in the plasma between the electrodes 111 and 112 to result in the material deposited on the substrate 9.

According to the embodiment of FIG. 32 the electrode body 31 is located in and distant from a housing 36 of a metallic material or of a dielectric material. If the housing 36 is of a metallic material, it is operated in an electrically floating manner or on an electric reference potential as e.g. on system ground potential G. The working-gas reservoir 29, containing e.g. argon, supplies working gas WG into the interspace V between the electrode body 31 and the housing 36. In one embodiment of the apparatus the working gas WG fed to the overall apparatus is fed to the housing 36.

The interspace V communicates via a coupling opening 38a or 38b with the reaction space RS. This coupling opening 38a or 38b is large enough to allow the plasma PLA to expand into the interspace V. The working gas WG flows from the interspace V into the reaction space RS through the coupling opening 38a or 38b. Additional supply of working gas WG into the reaction space may or may not be necessary. If a reactive gas is used or, as in PECVD, a material-component to be deposited on a substrate in gaseous form, such gas RG is fed to the reaction space RS outside the housing 36 and/or within the interspace V. In one embodiment of the apparatus, such gas RG is fed to the reaction space RS remote from the housing 36 as shown in FIG. 32.

Due to the pressure stage effect of the coupling opening 38a or 38b the working gas WG may have in the interspace V a slightly higher pressure than in the reaction space RS, leading to a shorter mean free path and thus darkspace distance in the interspace V, than in the reaction space RS.

The housing 36 may be a maintenance replace part and thus mounted in a manner to be easily exchanged.

Alternatively, or additionally, the inner surface of the housing 36 may be protected by a shield-inlay 70 as shown in dash line. The shield inlay 70 is an easily maintenance—replaceable part.

If the shield-inlay 70 is of a metallic material, then it is operated either in an electrically floating manner or on an electric reference potential, e.g. on system ground potential G. Alternatively the shield-inlay 70 may be of dielectric material.

The body 31 should not be directly seen from the substrate carrier 7, especially not from substrates 9 thereon. This to avoid that material sputtered from the body 31 deposits on the substrate 9. This is achieved by respective positioning and shaping of the coupling opening 38 and/or by a movable shutter 72 between the body 31 and the substrate carrier 7. If the coupling opening is tailored as schematically shown at 38a, the housing 36 itself bars the lines of sight LS 31 from the substrate carrier 7 to the body 31. If the coupling opening is tailored as schematically shown at 38b, then the respective baring is realized by means of a shutter 72, which may be movable to account for different needs e.g. with respect to different substrates. If made of a metallic material, the shutter 72 is either operated in an electrically floating manner or on a reference electric potential, e.g. on system ground potential G.

If necessary, the housing 36 may be cooled by providing an arrangement of channels for a cooling fluid along the wall of the housing 36 (not shown in the figure).

If a first plasma electrode 111 is applied in combination with a plasma treatment station, which customarily has its own two plasma electrodes, as e.g. a magnetron sputtering station, the one plasma electrode of such station, at a magnetron sputtering station the anode, may be replaced by the first plasma electrode 111 according to the invention.

As shown in FIG. 32 in dash line at W in some embodiments the first electrode 111 may be mounted in the housing 36 adjustable with respect to its position, especially with respect to its position along the axis A. The first plasma electrode may even be mounted removable from and reintroduceable into the housing 36. This may be advantageous for optimizing plasma ignition and for tuning the current path between the first and the second plasma electrodes, 111, 112.

If more than one plasma treatment stations operate into a common reaction space the respective plasmas of the plasma treatment stations may be served by a single first plasma electrode 111 according to the invention.

FIG. 33 and 34 show, most schematically and simplified, a top and a cross-sectional view of an embodiment of an arrangement according to the invention.

In the vacuum recipient 3 a substrate carrier 7 is drivingly rotatable. The substrate carrier 7 carries substrates 9. The substrates 9 pass along their moving pass a number, e.g. five plasma treatment stations 50 which all operate into the common reaction space RS. Each of the plasma treatment stations 50 comprises a second plasma electrode 112. At one locus along the vacuum recipient, e.g. where a further treatment station might be mounted, the first electrode 111 according to the invention is mounted. As shown by the respective plasma supply source arrangements 18 the first plasma electrode 111 is a plasma electrode common to the plasma treatment stations 50. The plasma treatment stations 50 with the common first electrode 111 may be operated simultaneously or subsequently or in a manner in which they operate simultaneously only during a part of their respective operating times, thus in fact in an “overlapping” timespan.

FIG. 35 shows most schematically and simplified a plasma treatment arrangement according to the invention. A plasma PLA is operated between the second plasma electrode 112 and the first plasma electrode 111. A plasma treatment station 78 operates in the common reaction space RS. A plasma PLS of the plasma treatment station 78 exploits the wall of the vacuum recipient 3 as a first electrode and the therefor the resulting plasma becomes relatively widespread in the reaction space RS.

In opposition thereto, the current path between the two plasma electrodes 111 and 112 concentrates on the first plasma electrode 111 and there on the second surface areas -PL- of the surface pattern. Thus the plasma PLA to the first plasma electrode 111 is concentrated towards the locally well-defined first plasma electrode 111 according to the invention. Thereby the plasma PLA becomes substantially decoupled from the plasma PLS as often required.

As was already addressed, the invention is most suited to be applied in magnetron sputter sources, in that the second plasma electrode 112 is the target or target holder and the first electrode 111 is the counter electrode, i.e. the “anode”. Thereby the target may be a silicon target. If at such a magnetron sputter source reactive sputtering is performed, the reactive gas may be oxygen or hydrogen, so as to deposit on the substrate 9 silicon oxide or a hydrogenated silicon layer.

In the FIGS. 36 to 48 a more specific apparatus according to the invention is schematically shown.

According to FIGS. 36 and 37 a substrate conveyer 201 is rotatable around an axis A1 driven by means of a drive 203, continuously at least for a 360° rotation. A multitude of substrates 9 resides on the substrate conveyer 201, held by respective substrate carriers (not shown), equidistant from the axis A1.

Along their rotational path, the substrates 9 pass at least two vacuum treatment stations 205 at least one thereof being a vacuum plasma treatment station thereby especially a magnetron sputter station as shown at 205a, with a target 207. In one embodiment at least two magnetron sputter stations 205a are provided as shown in FIG. 37. The vacuum treatment stations, and thereby especially the vacuum plasma treatment stations do all act on the substrates 9 commonly in the reaction space RS.

At the vacuum plasma treatments stations, including the one or more than one magnetron sputter stations 205a the first plasma electrode 111 in a housing 36 is commonly realized and located coaxially to the axis A1. The working gas -WG- inlet to the reaction space RS is provided at the housing 36 whereas, if provided, reactive gas RG is fed to the reaction space RS directly or via the respective vacuum treatment stations 205, thereby to the one or more than one magnetron sputter stations 205a.

The housing 36 is separated from the reaction space RS by means of a dielectric material shield 209 which may be said a part of the wall of the housing 36. The opening 38 according to FIG. 36 is provided through the shield 209. In one embodiment in which at least two magnetron sputter sources 205a are provided, the targets of the at least two magnetron sputter sources 205a are of silicon, one of these sources fed with oxygen as reactive gas RG, the other with hydrogen as reactive gas RG. As working gas WG argon may be used. The respective reactive gases may be fed to the reaction space RS nearby the targets 207, instead of being fed into the magnetron sputter sources.

In dash line the resulting plasma PLA from the targets 207 as second plasma electrodes 112 concentrated to the common first electrode 111 is qualitatively shown.

The body 31 of the first electrode 111 in the embodiment of FIGS. 36 and 37 may be realized according to any of the embodiments as where described before, extending along a linear axis, as along axis A1.

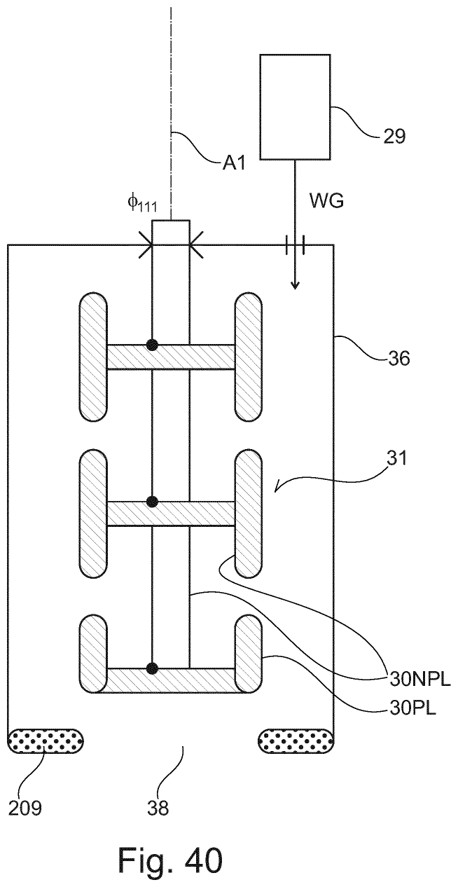

FIGS. 40 to 48 show different embodiments of the first plasma electrode 111 in the housing 36 as examples of such electrodes applied to the apparatus according to the FIGS. 36 and 37. Please note that the hatching in these figures as well does not indicate a cross-section.

The same reference numbers are used for same entities as applied before, and thus the skilled artisan perfectly understands these embodiments.

FIG. 42 is a schematic cross-sectional view of the example of FIG. 41, FIG. 45 a schematic cross-sectional view of the example of FIG. 44 and FIG. 48 a schematic cross-sectional view of the example of FIG. 47.

What is claimed is:

1) A vacuum plasma treatment apparatus comprising, within a vacuum recipient a substrate carrier, at least one first and at least one second plasma electrode for generating a plasma therebetween;
said first and second plasma electrodes being connectable to an electric plasma supply source arrangement establishing a first electric potential to said first plasma electrode and a second electric potential to said second plasma electrode, said first and said second electric potentials may both be set independently with respect to a system ground potential;
at least said first plasma electrode comprising an electrode body with an outer, patterned surface comprising first surface areas noncontributing to plasma electrode effect and being of a metallic material or of a dielectric material and second surface areas being plasma electrode effective and being of a metallic material or the surface of a dielectric material layer deposited on metallic material, said metallic material being operated on said first electric potential.

2) The vacuum plasma treatment apparatus of claim 1 wherein, in a new state of at least said first plasma electrode, and in a projection of said pattern on an envelope locus of said body, the ratio Q of the sum of projection areas of said second surface areas to the sum of projection areas of said first surface areas of said pattern being
0.1≤Q≤9.

3) The vacuum plasma treatment apparatus of claim 1 wherein, in a new state of at least said first plasma electrode, and in a projection of said pattern on an envelope locus of said body, the ratio Q of the sum of projection areas of said second surface areas to the sum of projection areas of said first surface areas of said pattern being
0.4≤Q≤1.

4) The vacuum plasma treatment apparatus of claim 1, at least some of said second surface areas and at least some of said first surface areas being metallic material surface areas, in a new state of at least said first plasma electrode.

5) The vacuum plasma treatment apparatus of claim 1, at least some of said first surfaces areas being dielectric material surfaces and at least some of said second surface areas being metallic material surfaces, in a new state of at least said first plasma electrode

6) The vacuum plasma treatment apparatus of claim 1, at least some of said first surface areas and at least some of said second surface areas being dielectric material surface areas in a new state of at least said first plasma electrode.

7) The vacuum plasma treatment apparatus of claim 1, wherein said body comprises a core and an envelope and the pattern of said patterned surface is defined by said envelope.

8) The vacuum plasma treatment apparatus of claim 7 wherein said envelope is a maintenance replace part.

9) The vacuum plasma treatment apparatus of claim 1, said second surface areas being of a metallic material in a new state of said at least first plasma electrode , and said vacuum plasma arrangement being constructed to generate, in operation, material in a space in said vacuum recipient exposed to at least said first plasma electrode, which material is electrically less conductive than said metallic material of said second surface areas.

10) The vacuum plasma treatment apparatus of claim 1, wherein said electrode body extends along a straight axis.

11) The vacuum plasma treatment apparatus of claim 1, wherein said electrode body is surrounded by a geometric locus-body which has an elliptical or a circular or a polygonal cross section.

12) The vacuum plasma treatment apparatus of claim 1, wherein said electrode body is surrounded by a geometric locus-body having, considered in one direction, a tapering cross-section contour.

13) The vacuum plasma treatment apparatus of claim 1, wherein said first surface areas of said patterned surface comprise at least one of
a void recess having a metallic material surface;
a void recess having a metallic material surface covered
by a layer of a dielectric material;
a recess having a metallic material surface and filled
with dielectric material.

14) The vacuum plasma treatment apparatus of claim 1, wherein at least some of said first surface areas of said pattern are areas of dielectric material on metallic material.

15) The vacuum plasma treatment apparatus of claim 14 wherein said second surface areas of said pattern are areas of dielectric material on metallic material whereby said areas of dielectric material of said second surface areas are thinner than said areas of dielectric material of said first surface areas and/or the dielectric constant of the dielectric material of the second surface areas is larger, than the dielectric constant of the dielectric material of the first surface areas.

16) The vacuum plasma treatment apparatus of claim 1, wherein said electrode body extends along an axis, said first surface areas comprising at least one groove around said axis.

17) The vacuum plasma treatment apparatus of claim 16 said at least one groove being a helical groove or a ring groove.

18) The vacuum plasma treatment apparatus of claim 1, wherein said second surface areas comprise at least one helical area around an axis of said body.

19) The vacuum plasma treatment apparatus of claim 18 wherein said helical area is a metallic material wire.

20) The vacuum plasma treatment apparatus of claim 18 wherein said helical wire is free-standing.

21) The vacuum plasma treatment apparatus of claim 1, wherein said first surface areas comprise interspaces between projecting webs.

22) The vacuum plasma treatment apparatus of claim 1, wherein said first surface areas comprise at least one interspace between mutually spaced metallic material plates.

23) The vacuum plasma treatment apparatus of claim 1, wherein said first surface areas comprise at least one dielectric material plate sandwiched between metallic material plates.

24) The vacuum plasma treatment apparatus of claim 1, wherein said body is cooled.

25) The vacuum plasma treatment apparatus of claim 1, wherein said body comprises a channel arrangement for a cooling medium or is mounted to a heat sink.

26) The vacuum plasma treatment apparatus of claim 1, further comprising an impedance element interconnected between a metallic material part of said body of said first plasma electrode and a part of said apparatus operated on an electric reference potential.

27) The vacuum plasma treatment apparatus of claim 1, further comprising a negative feedback control loop for controlling at least one of said first electric potential, of said second electric potential, of said potential difference.

28) The vacuum plasma treatment apparatus of claim 1, further comprising a negative feedback control loop wherein a measured prevailing entity consists of the first electric potential to be negative feedback controlled and comprising a sensing element for said first electric potential with respect to a reference electric potential.

29) The vacuum plasma treatment apparatus of claim 1, further comprising a negative feedback control loop wherein a measured prevailing entity consists of or comprises the first electric potential and comprising a sensing element for said first electric potential with respect to a reference electric potential, the adjusted entity in said negative feedback control loop consisting of or comprising a reactive gas flow and/or said electric potential difference between said first and said second plasma electrodes and comprising an adjustable flow controller for said reactive gas into the vacuum recipient and/or an adjustable plasma power supply arrangement for said electric potential difference.

30-39. (canceled)

40) The vacuum plasma treatment apparatus of claim 1, said body of said first plasma electrode being hidden from the lines of sight from said substrate carrier.

41-42. (canceled)

43) The vacuum plasma treatment apparatus of claim 1, said shutter being of a dielectric material.

44) The vacuum plasma treatment apparatus of claim 1, wherein said second plasma electrode is constructed according to the first plasma electrode.

45) The vacuum plasma treatment apparatus of claim 1, said second plasma electrode being a target or a target holder of a magnetron sputtering source or a substrate holder or a substrate of a plasma etching source and having a source anode consisting of said first plasma electrode.

46) The vacuum plasma treatment apparatus of claim 1, said second plasma electrode being a target of a magnetron sputtering source the target being of silicon.

47) The vacuum plasma treatment apparatus of claim 1, said vacuum recipient comprising a reactive gas inlet connectable or connected to a reactive gas reservoir.

48) The vacuum plasma treatment apparatus of claim 47 wherein said reactive gas is one of oxygen and of hydrogen.

49) The vacuum plasma treatment apparatus of claim 48 said second electrode being a magnetron sputter target of silicon.

50) (canceled)

51) The vacuum plasma treatment apparatus of claim 1, further comprising a first number of said second plasma electrodes and a second number of said first plasma electrodes, said second number being smaller than said first number.

52) The vacuum plasma treatment apparatus of claim 51 wherein said first number is at least two and said second number is one.

53) The vacuum plasma treatment apparatus of claim 1, further comprising
Within the vacuum recipient, a substrate conveyer, drivingly rotatable around an axis and comprising a multitude of substrate carriers equidistant from said axis;
More than one vacuum treatment stations aligned with the conveying path of said substrate carriers;
At least two of said more than one vacuum treatment stations comprising each a second plasma electrode, the first plasma electrode for said at least two vacuum treatment stations being common for said at least two vacuum treatment stations and being provided coaxially to said axis.

54) The vacuum plasma treatment apparatus of claim 53 said more than one vacuum treatment stations comprising at least two magnetron sputter stations with said common first plasma electrode.

55) The vacuum plasma treatment apparatus of claim 54 said at least two magnetron sputter stations having each a target of silicon.

56) The vacuum plasma treatment apparatus of claim 54, one of said at least two magnetron sputter stations being in flow communication with a reactive gas inlet connected or connectable to a gas reservoir containing hydrogen, the other of said at least two magnetron sputter stations being in flow communication with a reactive gas inlet connected or connectable to a gas reservoir containing oxygen.

57) The vacuum plasma treatment apparatus of claim 53, wherein said substrate conveyer is continuously driven by said drive at least for one 360° rotation and said magnetron sputter sources are continuously sputter-enabled at least during said one 360° rotation.

58-64. (canceled)

65) The vacuum plasma treatment apparatus of claim 26 wherein said part of said apparatus is operated on system ground potential.
